(19) United States
(12) Patent Application Publication
(10) Pub. No.: US 2024/0237486 A9
(43) Pub. Date: Jul. 11, 2024

(54) DISPLAY DEVICE AND METHOD OF FABRICATING THE SAME

(71) Applicant: Samsung Display Co., LTD., Yongin-si (KR)

(72) Inventors: Woo Yong SUNG, Yongin-si (KR); Seung Yong SONG, Yongin-si (KR); Jeong Seok LEE, Yongin-si (KR)

(21) Appl. No.: 18/224,734

(22) Filed: Jul. 21, 2023

(30) Foreign Application Priority Data
Oct. 21, 2022 (KR) 10-2022-0136080

(51) Int. Cl. H10K 59/80; H10K 59/12; H10K 59/121; H10K 59/122; H10K 59/131; H10K 71/20

(52) U.S. Cl. CPC H10K 59/873; H10K 59/1201; H10K 59/1213; H10K 59/122; H10K 59/131; H10K 71/231

(57) ABSTRACT

A display device includes a substrate including a display area and a non-display area; a light-emitting array layer; an encapsulation structure; pads disposed in a pad area which is a part of the non-display area on the substrate; a dam structure disposed in the non-display area on the substrate and surrounding an edge of the display area; an encapsulation auxiliary structure corresponding to another part of the non-display area except the pad area, surrounding a part of an edge of the display area, and disposed between the dam structure and an edge of the substrate; and a first multilayer disposed between the substrate and each of the dam structure and the encapsulation auxiliary structure, and including an undercut structure by two or more different metal materials which are stacked.

This application claims priority to Korean Patent Application No. 10-2022-0136080, filed on Oct. 21, 2022, and all the benefits accruing therefrom under 35 U.S.C. § 119, the content of which in its entirety is herein incorporated by reference.

### BACKGROUND

### 1. Field

The disclosure relates to a display device and a method of fabricating the same.

### 2. Description of the Related Art

With an advance of information-oriented society, more and more demands are placed on display devices for displaying images in various ways. The display device may be a flat panel display device such as a liquid crystal display, a field emission display and a light-emitting display.

A light-emitting display device may include an organic light-emitting display device including an organic light-emitting diode as a light-emitting element or a light-emitting diode display device including an inorganic light-emitting diode such as a light-emitting diode (“LED”) as a light-emitting element.

The organic light-emitting diode display includes a plurality of organic light-emitting diodes respectively disposed in a plurality of emission areas corresponding to a plurality of sub-pixels. Further, the organic light-emitting diode display may display an image by adjusting the luminance or grayscale of light of the organic light-emitting diode using the magnitude of the driving current applied to each of the plurality of organic light-emitting diodes.

The organic light-emitting diode of the organic light-emitting diode display includes a light-emitting layer including an organic light-emitting material for converting a driving current into a photon, but the organic light-emitting material is disadvantageous in that it may quickly deteriorate by moisture or oxygen. Accordingly, the organic light-emitting diode display may include an encapsulation structure for blocking the light-emitting layer from moisture or oxygen.

### SUMMARY

Features of the disclosure provide a display device capable of blocking permeation of oxygen or moisture into a light-emitting layer while disposing an encapsulation structure without a separate mask, and a method of fabricating the same.

In an embodiment of the disclosure, a display device includes a substrate including a display area in which a plurality of emission areas is arranged to display an image, and a non-display area disposed around the display area; a light-emitting array layer disposed in the display area on the substrate; an encapsulation structure disposed on the substrate and covering the light-emitting array layer; pads disposed in a pad area which is a part of the non-display area on the substrate; a dam structure disposed in the non-display area on the substrate and surrounding an edge of the display area; an encapsulation auxiliary structure corresponding to another part of the non-display area except the pad area, surrounding a part of the edge of the display area, and disposed between the dam structure and an edge of the substrate; and a first multilayer disposed between the substrate and each of the dam structure and the encapsulation auxiliary structure, and including an undercut structure by two or more different metal materials which are stacked.

In an embodiment, the first multilayer may include a first main layer, and a first cover layer disposed on the first main layer, The first main layer and the first cover layer may include different metal materials from each other. The undercut structure of the first multilayer may be provided by the first cover layer including an edge protruding beyond the first main layer.

In an embodiment, the encapsulation structure may include a first encapsulation layer corresponding to an area of the substrate except the pad area, covering the light-emitting array layer, and including an inorganic insulating material; a second encapsulation layer disposed on the first encapsulation layer, including an organic insulating material, and corresponding to a region surrounded by the dam structure; and a third encapsulation layer disposed on the first encapsulation layer, covering the second encapsulation layer, and including the inorganic insulating material. The first encapsulation layer may contact the first main layer of the first multilayer. The first encapsulation layer and the third encapsulation layer may contact each other in an area between the dam structure and the edge of the substrate in the non-display area.

In an embodiment, the light-emitting array layer may include a plurality of anode electrodes respectively corresponding to the plurality of emission areas; a bank buffer layer corresponding to a non-emission area which is a separation region between the plurality of emission areas and covering an edge of each of the plurality of anode electrodes; a second multilayer disposed on the bank buffer layer, and including an undercut structure by two or more different metal materials which are stacked; a pixel defining layer disposed on the second multilayer; a first common layer disposed on the plurality of anode electrodes and the pixel defining layer; a plurality of light-emitting layers respectively corresponding to the plurality of emission areas and disposed on the first common layer; a second common layer disposed on the first common layer and covering the plurality of light-emitting layers; and a cathode electrode disposed on the second common layer and corresponding to the plurality of emission areas. The first common layer, the second common layer, and the cathode electrode correspond to an area of the substrate except the pad area.

In an embodiment, the second multilayer may include a second main layer, and a second cover layer disposed on the second main layer, The second main layer and the second cover layer may include different metal materials from each other. The undercut structure of the second multilayer may be provided by the second cover layer including an edge protruding beyond the second main layer. The first encapsulation layer may cover the cathode electrode and contact the second main layer of the second multilayer.

In an embodiment, each of the first common layer, the second common layer, and the cathode electrode may be separated by the undercut structure of the second multilayer disposed under the pixel defining layer. The cathode electrode may include a plurality of portions respectively disposed on the plurality of anode electrodes. The plurality of portions of the cathode electrode may contact the second main layer of the second multilayer and be electrically connected to each other through the second multilayer.

In an embodiment, the bank buffer layer, the first common layer, the second common layer, and the cathode electrode may extend to the another part of the non-display area except the pad area.

In an embodiment, the first common layer, the second common layer, and the cathode electrode may cover the dam structure and the encapsulation auxiliary structure. Each of the first common layer, the second common layer, and the cathode electrode may be separated by the undercut structure of the first multilayer disposed under each of the dam structure and the encapsulation auxiliary structure.

In an embodiment, each of the first main layer and the second main layer may include aluminum (Al) or copper (Cu). Each of the first cover layer and the second cover layer may include titanium (Ti) or molybdenum (Mo).

In an embodiment, the first multilayer may further include a first support layer disposed between the substrate and the first main layer and including a metal material different from the metal material of the first main layer. The second multilayer may further include a second support layer disposed between the bank buffer layer and the second main layer and including a metal material different from the metal material of the second main layer.

In an embodiment, the bank buffer layer may be spaced apart from an upper portion of the edge of each of the plurality of anode electrodes.

In an embodiment, the display device may further include a sacrificial layer disposed between the bank buffer layer and each of the plurality of anode electrodes. The bank buffer layer may include an edge protruding beyond the sacrificial layer.

In an embodiment, the first multilayer and the second multilayer may be provided in a same layer. The dam structure, the encapsulation auxiliary structure, and the pixel defining layer may be provided in a same layer.

In an embodiment, the display device may further include a circuit array layer disposed on the substrate and including a plurality of pixel drivers respectively corresponding to the plurality of emission areas. Each of the plurality of pixel drivers may include at least one transistor. Each of the at least one transistor may include a semiconductor layer disposed on the substrate, a gate electrode disposed on a gate insulating layer covering the semiconductor layer, and a source electrode and a drain electrode disposed on an inter-insulating layer covering the gate electrode. The circuit array layer may include a first planarization layer disposed on the inter-insulating layer and covering the at least one transistor of each of the plurality of pixel drivers; a plurality of anode connection electrodes disposed on the first planarization layer and connected to the plurality of pixel drivers, respectively; and a second planarization layer covering the plurality of anode connection electrodes. The plurality of anode electrodes may be disposed on the second planarization layer and be respectively connected to the plurality of anode connection electrodes. The dam structure may be disposed on the second planarization layer. The encapsulation auxiliary structure may be disposed on the inter-insulating layer.

In an embodiment of the disclosure, a method of fabricating a display device includes providing a substrate including a display area in which a plurality of emission areas is arranged to display an image, and a non-display area disposed around the display area; disposing a circuit array layer on the substrate, the circuit array layer including a plurality of pixel drivers respectively corresponding to the plurality of emission areas, and pads in a pad area which is a part of the non-display area; disposing a plurality of anode electrodes respectively corresponding to the plurality of emission areas and a plurality of sacrificial layers respectively stacked on the plurality of anode electrodes on the circuit array layer; disposing an inorganic insulating material layer covering the plurality of sacrificial layers on the circuit array layer; disposing two or more metal material layers different from each other on the inorganic insulating material layer; disposing a pixel defining layer corresponding to a non-emission area which is a separation region between the plurality of emission areas, a dam structure corresponding to the non-display area and surrounding an edge of the display area, and an encapsulation auxiliary structure corresponding to another part of the non-display area except the pad area, surrounding a part of the edge of the display area, and disposed between the dam structure and an edge of the substrate on the two or more metal material layers; patterning the two or more metal material layers and the inorganic insulating material layer using the pixel defining layer, the dam structure, and the encapsulation auxiliary structure as a mask, providing a first multilayer including the two or more metal material layers remaining under each of the dam structure and the encapsulation auxiliary structure, providing a second multilayer including the two or more metal material layers remaining under the pixel defining layer, and providing a bank buffer layer including the inorganic insulating material layer remaining under each of the first multilayer and the second multilayer; deforming the first multilayer and the second multilayer into an undercut structure, and patterning the plurality of sacrificial layers to expose the plurality of anode electrodes; disposing a first common layer corresponding to an entirety of the area of the substrate on the plurality of anode electrodes, the pixel defining layer, the dam structure, and the encapsulation auxiliary structure; disposing a plurality of light-emitting layers respectively corresponding to the plurality of emission areas on the first common layer; disposing a second common layer corresponding to the entirety of the area of the substrate and covering the plurality of light-emitting layers on the first common layer; disposing a cathode electrode corresponding to the entirety of the area of the substrate on the second common layer; disposing a first encapsulation layer corresponding to the entirety of the area of the substrate on the cathode electrode; disposing a second encapsulation layer corresponding to a region surrounded by the dam structure on the first encapsulation layer; disposing a third encapsulation layer corresponding to the entirety of the area of the substrate and covering the second encapsulation layer on the first encapsulation layer; and removing a part of each of the first common layer, the second common layer, the cathode electrode, the first encapsulation layer, and the third encapsulation layer corresponding to the pad area, and exposing the pads.

In an embodiment, in the removing the part of each of the first common layer, the second common layer, the cathode electrode, the first encapsulation layer, and the third encapsulation layer corresponding to the pad area, an etching process may be performed on the first common layer, the second common layer, the cathode electrode, the first encapsulation layer, and the third encapsulation layer using a mask in which an opening corresponding to the pad area is defined.

In an embodiment, the method may further include, before disposing the first common layer, disposing a peel-off auxiliary layer corresponding to the pad area on the circuit array layer. In the removing the part of each of the first common layer, the second common layer, the cathode electrode, the first encapsulation layer, and the third encapsulation layer corresponding to the pad area, an etching process may be performed on the first common layer, the second common layer, the cathode electrode, the first encapsulation layer, and the third encapsulation layer using the peel-off auxiliary layer.

In an embodiment, in the sequentially stacking the two or more metal material layers, the two or more metal material layers may include a first metal material layer disposed on the inorganic insulating material layer, and a second metal material layer disposed on the first metal material layer, The first main layer and the first cover layer may include different metal materials from each other. In the providing the first multilayer and the second multilayer, the first multilayer may include a first main layer including the first metal material layer, and a first cover layer disposed on the first main layer and including the second metal material layer, and the second multilayer may include a second main layer including the first metal material layer, and a second cover layer disposed on the second main layer and including the second metal material layer.

In an embodiment, in the deforming the first multilayer and the second multilayer into the undercut structure, and the patterning the plurality of sacrificial layers to expose the plurality of anode electrodes, patterning may be performed on the plurality of sacrificial layers, the first main layer, and the second main layer. An edge of the first cover layer may protrude beyond the first main layer to deform the first multilayer into the undercut structure. An edge of the second cover layer may protrude beyond the second main layer to deform the second multilayer into the undercut structure. At least a part of each of the plurality of sacrificial layers may be removed to expose the plurality of anode electrodes.

In an embodiment, in the deforming the first multilayer and the second multilayer into the undercut structure, and the patterning the plurality of sacrificial layers to expose the plurality of anode electrodes, the bank buffer layer may be spaced apart from an upper portion of an edge of each of the plurality of anode electrodes.

In an embodiment, in the deforming the first multilayer and the second multilayer into the undercut structure, and the patterning the plurality of sacrificial layers to expose the plurality of anode electrodes, the bank buffer layer may include an edge protruding beyond a remaining portion of each of the plurality of sacrificial layers.

In an embodiment, in the disposing the first common layer, the first common layer disposed on the plurality of anode electrodes may be separated from the first common layer disposed on the pixel defining layer by the undercut structure of the second multilayer, and the first common layer disposed on the circuit array layer of the non-display area may be separated from the first common layer disposed on each of the dam structure and the encapsulation auxiliary structure. In the disposing the second common layer, the second common layer disposed on the plurality of anode electrodes may be separated from the second common layer disposed on the pixel defining layer by the undercut structure of the second multilayer, and the second common layer disposed on the circuit array layer of the non-display area may be separated from the second common layer disposed on each of the dam structure and the encapsulation auxiliary structure. In the disposing the cathode electrode, the cathode electrode disposed on the plurality of anode electrodes may be separated from the cathode electrode disposed on the pixel defining layer by the undercut structure of the second multilayer, and the cathode electrode disposed on the circuit array layer of the non-display area may be separated from the cathode electrode disposed on each of the dam structure and the encapsulation auxiliary structure.

In an embodiment, in the disposing the first encapsulation layer, the first encapsulation layer may contact each of the first main layer and the second main layer.

In an embodiment, in the disposing the cathode electrode, the cathode electrode may include portions respectively disposed above the plurality of anode electrodes. The portions of the cathode electrode may contact the second main layer of the second multilayer and be electrically connected to each other through the second multilayer.

In an embodiment, in the disposing the third encapsulation layer, the third encapsulation layer may contact the first encapsulation layer in a partial area between the edge of the substrate and the dam structure in the non-display area.

A display device in an embodiment includes an encapsulation structure covering a light-emitting array layer, a dam structure surrounding the edge of a display area, an encapsulation auxiliary structure corresponding to a region of a non-display area except a pad area and surrounding a part of the edge of the display area, and a first multilayer disposed between each of the dam structure and the encapsulation auxiliary structure and the substrate and including an undercut structure. Here, the first multilayer may include a first main layer, and a first cover layer disposed on the first main layer and including an edge protruding beyond the first main layer. Further, the encapsulation structure may include a first encapsulation layer including an inorganic insulating material and disposed in the area of the substrate except the pad area, a second encapsulation layer including an organic insulating material corresponding to the region surrounded by the dam structure and disposed on the first encapsulation layer, and a third encapsulation layer including an inorganic insulating material covering the second encapsulation layer and disposed on the first encapsulation layer. The first encapsulation layer may extend along the side surface of the first cover layer to contact the first main layer due to deposition characteristics of the inorganic insulating material.

That is, the first encapsulation layer covers the dam structure and the encapsulation auxiliary structure and contacts the first main layer of the first multilayer disposed under each of the dam structure and the encapsulation auxiliary structure.

Accordingly, the encapsulation structure may be provided by adhesion between the first encapsulation layer and the first multilayer, that is, adhesion between inorganic materials, without removing the organic insulating material disposed around the dam structure.

Further, since the first multilayer is disposed under each of the dam structure and the encapsulation auxiliary structure, the number of the adhesion structure between the inorganic materials by the first multilayer and the first encapsulation layer may correspond to the number of the dam structure and the number of the encapsulation auxiliary structure. Accordingly, the encapsulation structure for preventing permeation of oxygen or moisture may become more reliable.

In addition, in an embodiment, the light-emitting array layer may include a bank buffer layer covering edges of a plurality of anode electrodes, a second multilayer disposed on the bank buffer layer and having an undercut structure, a pixel defining layer disposed on the second multilayer, a first common layer disposed on the plurality of anode electrodes and the pixel defining layer, a plurality of light-emitting layers disposed on the first common layer and respectively corresponding to the plurality of emission areas, a second common layer disposed on the first common layer and covering the plurality of light-emitting layers, and a cathode electrode disposed on the second common layer. Here, the first common layer, the second common layer, and the cathode electrode may correspond to the area of the substrate except the pad area.

Further, in the encapsulation structure, the first encapsulation layer corresponds to the area of the substrate except the pad area, and the third encapsulation layer is disposed on the first encapsulation layer.

That is, each of the first common layer, the second common layer, the cathode electrode, the first encapsulation layer, and the third encapsulation layer is disposed in the area of the substrate except the pad area, and thus may be provided by a stacking process using no mask and a simultaneous patterning process corresponding to the pad area. Accordingly, the fabricating process of the display device may be further simplified and facilitated.

In addition, in the light-emitting array layer, the first common layer, the second common layer, and the cathode electrode disposed on the plurality of anode electrodes may be separated from the first common layer, the second common layer, and the cathode electrode disposed on the pixel defining layer by the undercut structure of the second multilayer. Accordingly, the leakage current between adjacent emission areas by the second common layer may be reduced, which makes it possible to prevent deterioration of the display quality of the display device due to the leakage current.

Further, since the first encapsulation layer contacts the second main layer of the second multilayer, each of the plurality of light-emitting layers may be more reliably encapsulated by adhesion between the first encapsulation layer and the second multilayer, that is, adhesion between inorganic materials. In other words, the plurality of light-emitting layers may be individually encapsulated by adhesion between the first encapsulation layer and the second multilayer. Accordingly, it may be more advantageous to prevent permeation of oxygen or moisture into each light-emitting layer. In addition, the expansion of permeation of oxygen or moisture to another neighboring light-emitting layer may be prevented.

Therefore, the deterioration of the display quality and the reduction in the lifetime of the display device may be suppressed.

The effects of the disclosure are not limited to the aforementioned effects, and various other effects are included in the specification.

### BRIEF DESCRIPTION OF THE DRAWINGS

The above and other embodiments and features of the disclosure will become more apparent by describing in detail embodiments thereof with reference to the attached drawings, in which:

FIG. 1 is a plan view illustrating an embodiment of a display device;

FIG. 2 is an enlarged plan view illustrating another embodiment of a part of the display area of FIG. 1;

FIG. 3 is an equivalent circuit diagram illustrating an embodiment of any one emission area of FIG. 1;

FIG. 4 is a cross-sectional view illustrating an embodiment of a surface taken along line A-A′ of FIG. 1 in a display device;

FIG. 5 is an enlarged view of part C of FIG. 4;

FIG. 6 is an enlarged view of part D of FIG. 4;

FIG. 7 is a cross-sectional view illustrating an embodiment of a surface taken along line B-B′ of FIG. 1 in a display device;

FIG. 8 is a cross-sectional view illustrating an embodiment of a surface taken along line A-A′ of FIG. 1 in a display device;

FIG. 9 is a cross-sectional view illustrating an embodiment of a surface taken along line B-B′ of FIG. 1 in a display device;

FIG. 10 is a flowchart illustrating an embodiment of a method of fabricating the display device;

FIGS. 11 to 29 are process views illustrating some operations of FIG. 10; and

FIGS. 30 to 32 are process views illustrating another embodiment of some operations of a method of fabricating a display device.

### DETAILED DESCRIPTION

The embodiments will now be described more fully hereinafter with reference to the accompanying drawings. The embodiments may, however, be provided in different forms and should not be construed as limiting. The same reference numbers indicate the same components throughout the disclosure. In the accompanying drawing figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it may be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments of the disclosure will be described in detail with reference to the accompanying drawings.

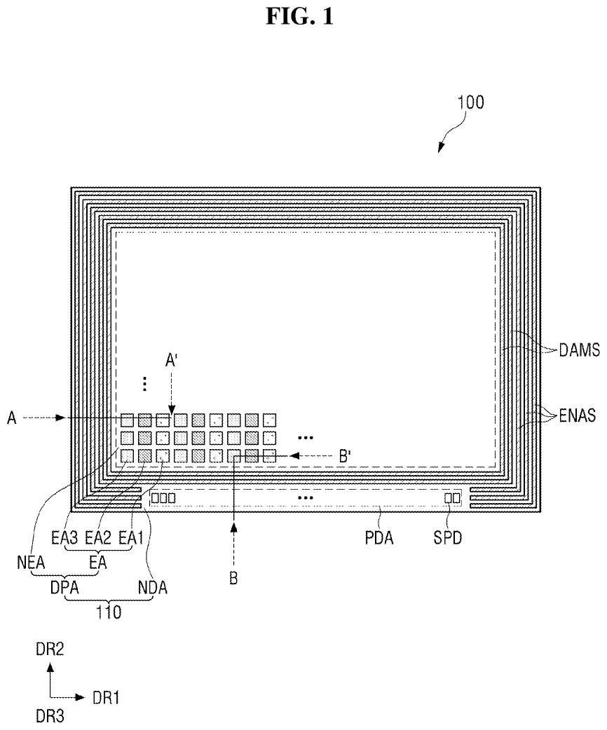

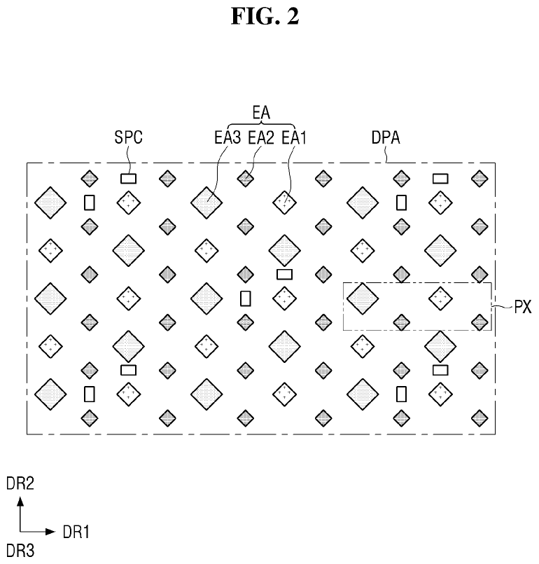

FIG. 1 is a plan view illustrating an embodiment of a display device. FIG. 2 is an enlarged plan view illustrating another embodiment of a part of the display area of FIG. 1.

Referring to FIG. 1, a display device 100 in an embodiment may be formed in a flat panel shape. The display device 100 in an embodiment is a device for displaying a moving image or a still image. The display device 100 may be used as a display screen of various products such as televisions, laptop computers, monitors, billboards and the Internet of Things (“IoT”) as well as portable electronic devices such as mobile phones, smart phones, tablet personal computers (“tablet PCs”), smart watches, watch phones, mobile communication terminals, electronic notebooks, electronic books, portable multimedia players (PMPs), navigation systems and ultra mobile PCs (“UMPCs”).

The display device 100 may be a light-emitting display device including a light-emitting element.

In an embodiment, the display device 100 may be at least one of an organic light-emitting display device using an organic light-emitting diode as a light-emitting element, a micro light-emitting diode display device using a micro light-emitting diode (“LED”) as a light-emitting element, a quantum dot organic light-emitting display device using a quantum dot and an organic light-emitting diode as a light-emitting element, or an inorganic light-emitting display device using an inorganic semiconductor as a light-emitting element, for example.

In the following description, it is assumed that the display device 100 is an organic light-emitting display device.

In an embodiment, the display device 100 may, in a plan view, be formed in a quadrangular shape, e.g., rectangular shape including long sides in a first direction DR1 and short sides in a second direction DR2 crossing the first direction DR1, for example. The corners formed by meeting of the long sides in the first direction DR1 and the short sides in the second direction DR2 may be rounded to have a predetermined curvature or may be right-angled. The planar shape of the display device 100 is not limited to a quadrilateral shape, and may be formed in another polygonal shape, a circular shape, or an elliptical shape. The display device 100 may be formed to be flat, but is not limited thereto. In an embodiment, the display device 100 may include a curved portion formed at left and right ends and having a predetermined curvature or a varying curvature, for example.

In addition, the display device 100 may be formed flexibly so that it may be curved, bent, folded, or rolled.

The display device 100 in an embodiment includes a substrate 110 including a display area DPA in which a plurality of emission areas EA is arranged to display an image, and a non-display area NDA disposed around the display area DPA, pads SPD in a pad area PDA which is a part of the non-display area NDA, a dam structure DAMS surrounding the edge of the display area DPA, and an encapsulation auxiliary structure ENAS corresponding to the region of the non-display area NDA except the pad area PDA and surrounding a part of the edge of the display area DPA.

The display area DPA is an area from which light for image display is emitted. The display area DPA may have a circular shape, an oval shape, or a polygonal shape. The display area DPA may be selected as a part of the center of the substrate 110.

The non-display area NDA, which is a peripheral area surrounding the display area DPA, is an area in which an image is not displayed. The non-display area NDA may be selected as an area between the edge of the display area DPA and the edge of the substrate 110.

The display area DPA includes a plurality of emission areas EA arranged side by side in the first direction DR1 and the second direction DR2, and a non-emission area NEA which is a separation region disposed between the plurality of emission areas EA.

Each of the plurality of emission areas EA may be a unit that is individually driven to display light of any one of two or more different colors with a predetermined luminance.

In an embodiment, the plurality of emission areas EA may include first emission areas EA1 emitting light of a first color in a predetermined wavelength band, second emission areas EA2 emitting light of a second color in a wavelength band lower than that of the first color, and third emission areas EA3 emitting light of a third color in a wavelength band lower than that of the second color, for example.

In an embodiment, the first color may be red having a wavelength band of approximately 600 nanometers (nm) to approximately 750 nm, the second color may be green having a wavelength band of approximately 480 nm to approximately 560 nm, and the third color may be blue having a wavelength band of approximately 370 nm to approximately 460 nm, for example. However, this is only one of embodiments, and the wavelength band of the light emitted from each of the first, second, and third emission areas EA1, EA2, and EA3 of this specification is not limited thereto.

A plurality of pixels, each including a combination of the first emission area EA1, the second emission area EA2, and the third emission area EA3 adjacent to each other among the plurality of emission areas EA, may be provided. The plurality of pixels may be a unit for individually displaying various colors including white. That is, lights of various colors displayed by the plurality of pixels may be implemented as a combination of lights emitted from two or more emission areas EA.

FIG. 1 illustrates the arrangement of the plurality of emission areas EA in which the first emission area EA1, the second emission area EA2, and the third emission area EA3 are alternately arranged in the first direction DR1. Here, the first emission areas EA1 may be arranged side by side in the second direction DR2, the second emission areas EA2 may be arranged side by side in the second direction DR2, and the third emission areas EA3 may be arranged side by side in the second direction DR2.

However, this is only one of embodiments, and the arrangement pattern of the emission areas EA of this specification is not limited to that illustrated in FIG. 1.

In another embodiment as illustrated in FIG. 2, the arrangement of the plurality of emission areas EA may include a row in which the first emission areas EA1 and the third emission areas EA3 are alternately arranged in the first direction DR1 or the second direction DR2, and a row in which the second emission areas EA2 diagonally adjacent to the first emission areas EA1 and the third emission areas EA3 are arranged side by side in the first direction DR1 or the second direction DR2.

In this case, each of the plurality of pixels PX may include any one first emission area EA1 and any one third emission area EA3 adjacent to each other in the first direction DR1 or the second direction DR2, and any two second emission areas EA2 adjacent thereto in a diagonal direction.

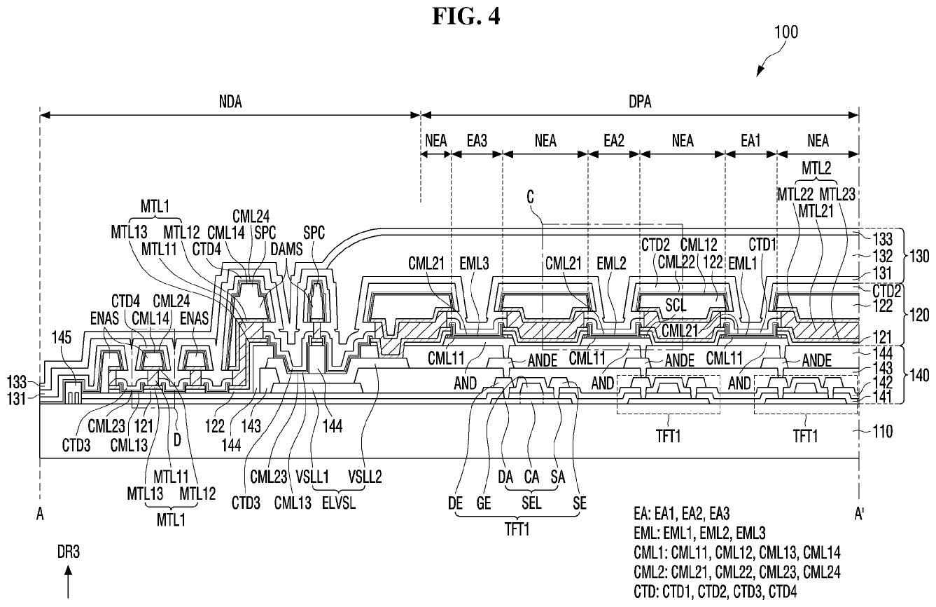

In addition, the display device 100 in an embodiment may further include a dam structure DAMS (refer to FIG. 1) and a spacer SPC corresponding to a part of the non-emission area NEA. The spacer SPC serves to support a mask used in a process of disposing a light-emitting layer EML (refer to FIG. 4) of each of the plurality of emission areas EA.

A plurality of spacers SPC may be arranged to be spaced apart from each other at intervals corresponding to two or more emission areas EA. In an embodiment, as illustrated in FIG. 2, among the plurality of spacers SPC, any two spacers SPC arranged side by side with the second emission area EA2 in the first direction DR1 may be spaced apart from each other with four second emission areas EA2 interposed therebetween, for example. Further, among the plurality of spacers SPC, any two spacers SPC arranged side by side with the second emission area EA2 in the second direction DR2 may be spaced apart from each other with four second emission areas EA2 interposed therebetween.

The arrangement pattern of the spacers SPC are not limited to that illustrated in FIG. 2, and may be variously changed.

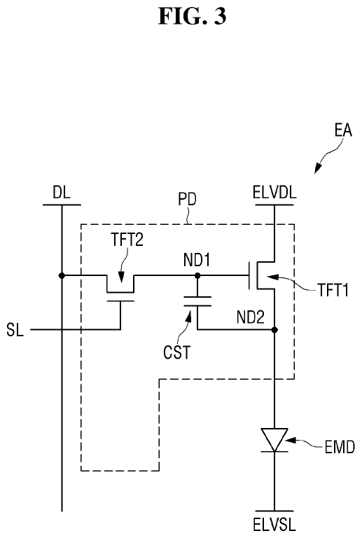

FIG. 3 is an equivalent circuit diagram illustrating an embodiment of any one emission area of FIG. 1.

The display device 100 in an embodiment may include a plurality of pixel drivers PD respectively corresponding to the plurality of emission areas EA (refer to FIG. 1).

The plurality of pixel drivers PD may supply a driving current to a plurality of light-emitting elements EMD corresponding to the plurality of emission areas EA, respectively.

Referring to FIG. 3, each of the plurality of pixel drivers PD may have a 2T1C structure including two transistors and one capacitor. However, the illustration of FIG. 3 is only one of embodiments, and the pixel driver PD of this specification is not limited to that illustrated in FIG. 3 and may be variously changed.

The light-emitting element EMD of each emission area EA may be an organic light-emitting diode including a light-emitting layer including an organic light-emitting material and interposed between an anode electrode and a cathode electrode facing each other.

The pixel driver PD of each emission area EA may include a first transistor TFT1, a second transistor TFT2, and a storage capacitor CST.

The first transistor TFT1 may be connected in series with the light-emitting element EMD between a first power line ELVDL for supplying a predetermined first power for driving the light-emitting element EMD and a second power supply line ELVSL for supplying a second power having a voltage level lower than that of the first power.

That is, the first transistor TFT1 may be disposed between the first power line ELVDL and the light-emitting element EMD.

The second transistor TFT2 may be disposed between a data line DL and the gate electrode of the first transistor TFT1. The gate electrode of the second transistor TFT2 may be connected to a scan line SL.

When the second transistor TFT2 is turned on based on the scan signal of the scan line SL, the second transistor TFT2 transfers the data signal of the data line DL to a first node ND1. The first node ND1 is the contact point between the gate electrode of the first transistor TFT1 and the second transistor TFT2.

The storage capacitor CST may be disposed between the first node ND1 and a second node ND2. The second node ND2 is the contact point between the first transistor TFT1 and the light-emitting element EMD.

The storage capacitor CST is charged with the data signal supplied to the first node ND1 and stores the voltage difference between the first node ND1 and the second node ND2.

The gate electrode of the first transistor TFT1 is connected to the first node ND1. When the first transistor TFT1 is turned on based on the data signal supplied to the first node ND1, the driving current corresponding to the voltage difference between the gate electrode and the first electrode may be outputted to the second electrode. Accordingly, the light-emitting element EMD may emit light having a luminance corresponding to the driving current of the first transistor TFT1.

A period in which the first transistor TFT1 is turned on may correspond to the charging voltage of the storage capacitor CST.

Although FIG. 3 illustrates a case in which the first and second transistors TFT1 and TFT2 are N-type metal oxide semiconductor field effect transistors (“MOSFET”), this is only one of embodiments. That is, at least one of the first and second transistors TFT1 and TFT2 may be a P-type MOSFET.

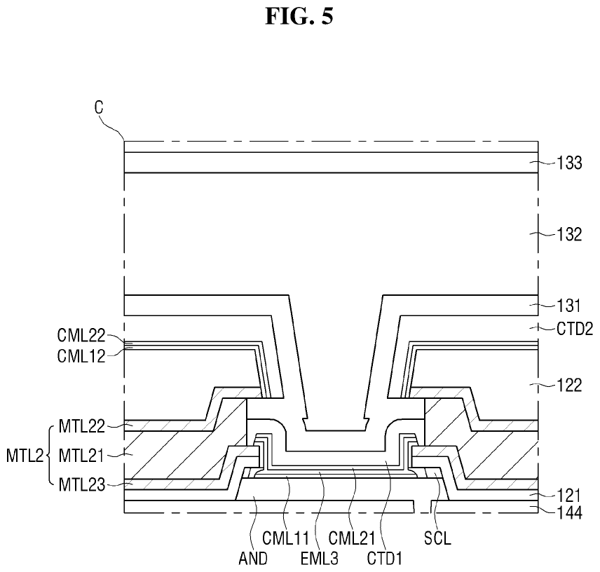

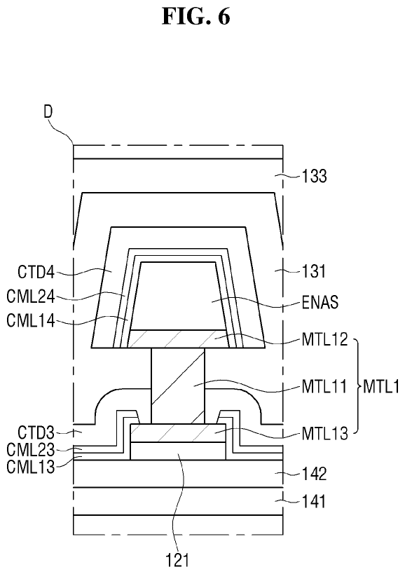

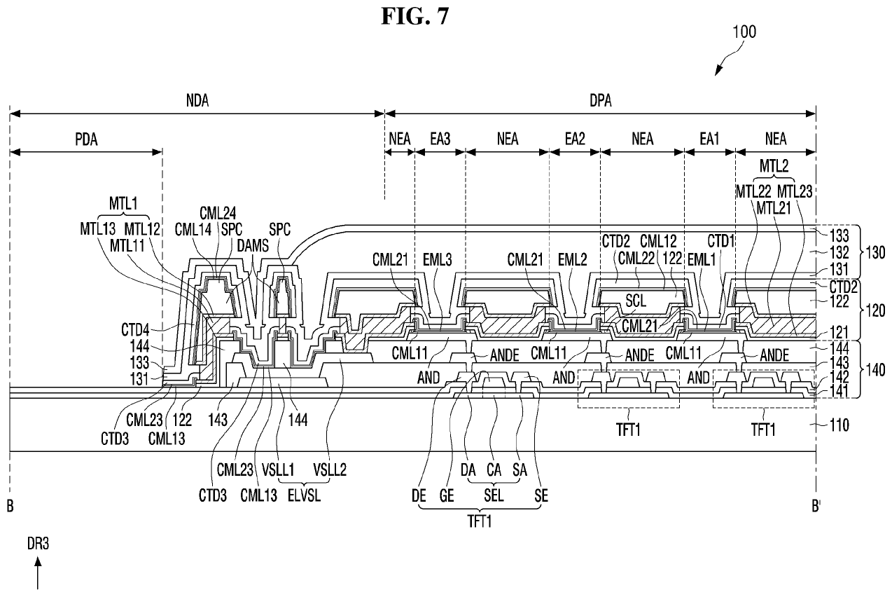

FIG. 4 is a cross-sectional view illustrating an embodiment of a surface taken along line A-A′ of FIG. 1 in a display device. FIG. 5 is an enlarged view of part C of FIG. 4. FIG. 6 is an enlarged view of part D of FIG. 4. FIG. 7 is a cross-sectional view illustrating an embodiment of a surface taken along line B-B′ of FIG. 1 in a display device.

Referring to FIGS. 5, 6, and 7, the display device 100 in an embodiment includes the substrate 110 including the display area DPA in which the plurality of emission areas EA1, EA2, and EA3 is arranged to display an image, and the non-display area NDA disposed around the display area DPA, a light-emitting array layer 120 disposed in the display area DPA on the substrate 110, an encapsulation structure 130 disposed on the substrate 110 and covering the light-emitting array layer 120, the pads SPD (refer to FIG. 1) disposed on the substrate 110 and corresponding to the pad area PDA which is a part of the non-display area NDA, the dam structure DAMS disposed in the non-display area NDA on the substrate 110 and surrounding the edge of the display area DPA, the encapsulation auxiliary structure ENAS corresponding to the region of the non-display area NDA except the pad area PDA and surrounding a part of the edge of the display area DPA and disposed between the dam structure DAMS and the edge of the substrate 110, and the first multilayer MTL1 disposed between the substrate 110 and each of the dam structure DAMS and the encapsulation auxiliary structure ENAS, and including two or more different metal materials which are stacked, and an undercut structure.

The first multilayer MTL1 includes a first main layer MTL11 and a first cover layer MTL12 that are sequentially stacked. That is, the first multilayer MTL1 includes a first main layer MTL11, and a first cover layer MTL12 disposed on the first main layer MTL11. The first main layer MTL11 includes or consists of a predetermined metal material. The first cover layer MTL12 includes or consists of a metal material different from that of the first main layer MTL11.

The first cover layer MTL12 has a width greater than that of the first main layer MTL11, so that the edge of the first cover layer MTL12 protrudes beyond the first main layer MTL11. Accordingly, the undercut structure of the first multilayer MTL1 may be provided by the first cover layer MTL12 including the edge protruding beyond the first main layer MTL11.

The first multilayer MTL1 may further include a first support layer MTL13 disposed between the substrate 110 and the first main layer MTL11 and including a metal material different from that of the first main layer MTL11. The first support layer MTL13 may include or consist of the same material as that of the first cover layer MTL12.

The encapsulation structure 130 may include a first encapsulation layer 131 disposed in the area of the substrate 110 except the pad area PDA and covering the light-emitting array layer 120 and including an inorganic insulating material, a second encapsulation layer 132 disposed on the first encapsulation layer 131 and including an organic insulating material and corresponding to the region surrounded by the dam structure DAMS, and a third encapsulation layer 133 disposed on the first encapsulation layer 131 and covering the second encapsulation layer 132 and including an inorganic insulating material.

The first encapsulation layer 131 contacts the first main layer MTL11 of the first multilayer MTL1. That is, the first encapsulation layer 131 may be stacked along the undercut structure of the first multilayer MTL1 to contact the first main layer MTL11 of the first multilayer MTL1.

Accordingly, the bonding structure between inorganic materials may be provided by bonding between the first encapsulation layer 131 and the first main layer MTL11 of the first multilayer MTL1 under each of the dam structure DAMS and the encapsulation auxiliary structure ENAS. Therefore, even when the organic insulating material of the non-display area NDA is not completely removed, the encapsulation structure formed by bonding between inorganic materials may be obtained by the first multilayer MTL1.

In addition, the display device 100 in an embodiment includes the encapsulation auxiliary structure ENAS disposed in a part of the non-display area NDA, in addition to the dam structure DAMS for disposing the second encapsulation layer 132. Accordingly, the encapsulation structures formed by bonding between the first encapsulation layer 131 and the first main layer MTL11 of the first multilayer MTL1 may be repeatedly arranged and, thus, more reliable encapsulation may be obtained.

Although FIGS. 1, 4, and 7 illustrate that two dam structures DAMS are spaced apart from each other, this is only one of embodiments, and the display device 100 in an embodiment may include one or more dam structures DAMS surrounding the edge of the display area DPA.

Further, although FIGS. 1 and 4 illustrate that three encapsulation auxiliary structures ENAS are spaced apart from each other, this is only one of embodiments, and the display device 100 in an embodiment may include two or more encapsulation auxiliary structures ENAS disposed around the dam structure DAMS and spaced apart from each other.

The third encapsulation layer 133 is disposed on the first encapsulation layer 131, and thus may contact the first encapsulation layer 131 in a region where the second encapsulation layer 132 is not disposed. That is, the first encapsulation layer 131 and the third encapsulation layer 133 may contact each other between the dam structure DAMS and the edge of the substrate 110 in the non-display area NDA.

The light-emitting array layer 120 may include a plurality of anode electrodes AND respectively corresponding to the plurality of emission areas EA, a bank buffer layer 121 corresponding to the non-emission area NEA which is a separation region disposed between the plurality of emission areas EA and covering the edges of the plurality of anode electrodes AND, a second multilayer MTL2 disposed on the bank buffer layer 121 and formed by stacking two or more different metal materials and including an undercut structure, a pixel defining layer 122 disposed on the second multilayer MTL2, a first common layer CML1 disposed on the plurality of anode electrodes AND and the pixel defining layer 122, a plurality of light-emitting layers EML disposed on the first common layer CML1 and respectively corresponding to the plurality of emission areas EA, a second common layer CML2 disposed on the first common layer CML1 and covering the plurality of light-emitting layers EML, and a cathode electrode CTD disposed on the second common layer CML2 and corresponding to the plurality of emission areas EA.

By the light-emitting array layer 120, in each of the plurality of emission areas EA, the light-emitting element EMD (refer to FIG. 3) including the anode electrode AND and the cathode electrode CTD1 facing each other, and the first common layer CML11, the light-emitting layer EML, and the second common layer CML21 that are disposed between the anode electrode AND and the cathode electrode CTD1 and sequentially stacked may be provided.

In an embodiment, the first common layer CML1 may include a hole transporting layer including an organic material, for example. That is, the first common layer CML1 may include or consist of an organic material having a property of transporting holes supplied from the anode electrode AND to the light-emitting layer EML.

In an alternative embodiment, the first common layer CML1 may further include a hole injecting layer disposed between the hole transporting layer and the anode electrode AND.

Further, the second common layer CML2 may include an electron transporting layer including an organic material. That is, the second common layer CML2 may include or consist of an organic material having a property of transporting electrons supplied from the cathode electrode CTD to the light-emitting layer EML.

In an alternative embodiment, the second common layer CML2 may further include an electron injecting layer disposed between the cathode electrode CTD and the electron transporting layer.

The plurality of light-emitting layers EML may include a first light-emitting layer EML1 corresponding to the first emission area EA1 and emitting light of the first color, a second light-emitting layer EML2 corresponding to the second emission area EA2 and emitting light of the second color, and a third light-emitting layer EML3 corresponding to the third emission area EA3 and emitting light of the third color.

The first common layer CML1, the second common layer CML2, and the cathode electrode CTD correspond to the area of the substrate 110 except the pad area PDA. That is, each of the first common layer CML1, the second common layer CML2, and the cathode electrode CTD is stacked on the entirety of the surface of the substrate 110 except the pad area PDA. Accordingly, the first common layer CML1, the second common layer CML2, and the cathode electrode CTD may be provided by a stacking process using no mask. Accordingly, the fabricating process may be further simplified and facilitated.

The second multilayer MTL2 includes a second main layer MTL21 including a predetermined metal material, and a second cover layer MTL22 disposed on the second main layer MTL21 and including a metal material different from that of the second main layer MTL21.

Since the second cover layer MTL22 has a width greater than that of the second main layer MTL21, the edge of the second cover layer MTL22 protrudes beyond the second main layer MTL21. Accordingly, the undercut structure of the second multilayer MTL2 may be provided by the second cover layer MTL22 including the edge protruding beyond the second main layer MTL21.

The second multilayer MTL2 may further include a second support layer MTL23 disposed between the substrate 110 and the second main layer MTL21 and including a metal material different from that of the second main layer MTL21. The second support layer MTL23 may include or consist of the same material as that of the second cover layer MTL22.

The second main layer MTL21 is formed in the same layer as the first main layer MTL11, the second cover layer MTL22 is formed in the same layer as the first cover layer MTL12, and the second support layer MTL23 is formed in the same layer as the first support layer MTL13.

The first encapsulation layer 131 of the encapsulation structure 130 covers the cathode electrode CTD, and contacts the second multilayer MTL2 of the display area DPA as well as the first multilayer MTL1 of the non-display area NDA. That is, the first encapsulation layer 131 disposed on the cathode electrode CTD is stacked along the undercut structure of the second multilayer MTL2, and thus may contact the second main layer MTL21 of the second multilayer MTL2.

Accordingly, as shown in FIG. 5, under the pixel defining layer 122 corresponding to the non-emission area NEA, a bonding structure between inorganic materials may be provided by bonding between the first encapsulation layer 131 and the second main layer MTL21. Accordingly, the plurality of light-emitting layers EML may be individually encapsulated, and thus may be more reliably blocked from permeation of oxygen or moisture.

The first common layer CML11, the second common layer CML21, and the cathode electrode CTD1 disposed on the plurality of anode electrodes AND may be separated from a first common layer CML12, a second common layer CML22, and a cathode electrode CTD2 disposed on the pixel defining layer 122 by the undercut structure of the second multilayer MTL2 disposed under the pixel defining layer 122.

Further, the cathode electrodes CTD1 disposed on the plurality of anode electrodes AND may contact the second main layer MTL21 of the second multilayer MTL2, and may be electrically connected to each other through the second multilayer MTL21. That is, the second multilayer MTL21 may function as a wire connected to the cathode electrodes CTD1 respectively corresponding to the plurality of emission areas EA.

In an embodiment, the bank buffer layer 121, the first common layer CML1, the second common layer CML2, and the cathode electrode CTD extend to the region of the non-display area NDA except the pad area PDA as well as the display area DPA.

Accordingly, as shown in FIG. 6, in the non-display area NDA, a first common layer CML13, a second common layer CML23, and a cathode electrode CTD3 cover the dam structure DAMS and the encapsulation auxiliary structure ENAS. Further, the first common layer CML13, the second common layer CML23, and the cathode electrode CTD3 disposed on each of the dam structure DAMS and the encapsulation auxiliary structure ENAS may be separated from a first common layer CML14, a second common layer CML24, and a cathode electrode CTD4 disposed around each of the dam structure DAMS and the encapsulation auxiliary structure ENAS by the undercut structure of the first multilayer MTL1 disposed under each of the dam structure DAMS and the encapsulation auxiliary structure ENAS.

In addition, the display device 100 in an embodiment may further include a circuit array layer 140 disposed on the substrate 110 and including the plurality of pixel drivers PD (refer to FIG. 3) respectively corresponding to the plurality of emission areas EA.

Each of the plurality of pixel drivers PD includes one or more transistors TFT1 and TFT2 (refer to FIG. 3).

Each of the one or more transistors TFT1 and TFT2 may include a semiconductor layer SEL disposed on the substrate 110, a gate electrode GE disposed on a gate insulating layer 141 covering the semiconductor layer SEL, and a source electrode SE and a drain electrode DE disposed on an inter-insulating layer 142 covering the gate electrode GE.

The circuit array layer 140 may include a first planarization layer 143 disposed on the inter-insulating layer 142 and covering the one or more transistors TFT1 and TFT2 (refer to FIG. 3) included in the plurality of pixel drivers PD, a plurality of anode connection electrodes ANDE disposed on the first planarization layer 143 and respectively connected to the plurality of pixel drivers PD, and a second planarization layer 144 covering the plurality of anode connection electrodes ANDE.

The plurality of anode electrodes AND are disposed on the second planarization layer 144 and are respectively connected to the plurality of anode connection electrodes ANDE.

The first planarization layer 143 and the second planarization layer 144 may extend to the region of the non-display area NDA corresponding to the dam structure DAMS, and the dam structure DAMS may be disposed on the second planarization layer 144.

The encapsulation auxiliary structure ENAS is disposed around the dam structure DAMS to be adjacent to the edge of the substrate 110. The encapsulation auxiliary structure ENAS may be disposed on the inter-insulating layer 142.

The substrate 110 may include or consist of an insulating material. In an embodiment, the first substrate 110 may include or consist of an insulating material such as glass, quartz, or polymer resin. In embodiments, the polymer resin may include polyethersulphone (“PES”), polyacrylate (“PA”), polyarylate (“PAR”), polyetherimide (“PEI”), polyethylene naphthalate (“PEN”), polyethylene terephthalate (“PET”), polyphenylene sulfide (“PPS”), polyallylate, polyimide (“PI”), polycarbonate (“PC”), cellulose triacetate (CAT), cellulose acetate propionate (“CAP”), or any combinations thereof.

The substrate 110 may include or consist of a rigid material to properly support components disposed on one surface thereof.

In an alternative embodiment, in order to facilitate shape deformation of the display device 100, the substrate 110 may include or consist of a flexible material that may be easily bent, folded, or rolled.

In an alternative embodiment, the substrate 110 may include or consist of a metal material.

The circuit array layer 140 disposed on the substrate 110 includes the plurality of pixel drivers PD respectively corresponding to the plurality of emission areas EA.

The plurality of pixel drivers PD may be respectively connected to the plurality of anode electrodes AND, and may include one or more transistors TFT1 and TFT2 (refer to FIG. 3).

In an embodiment, as shown in FIGS. 4 and 7, the first transistor TFT1 of each of the plurality of pixel drivers PD may include the semiconductor layer SEL, the gate electrode GE overlapping a channel area CA of the semiconductor layer SEL, and the source electrode SE and the drain electrode DE respectively connected to a source area SA and a drain area DA of the semiconductor layer SEL, for example.

In addition, although not shown separately, the second transistor TFT2 of each of the plurality of pixel drivers PD may have the same structure as that of the first transistor TFT1.

However, this is only one of embodiments, and the second transistor TFT2 may have a structure different from that of the first transistor TFT1. In an embodiment, the second transistor TFT2 may include a semiconductor layer formed in a different layer from the semiconductor layer SEL of the first transistor TFT1 and including a material different from that of the semiconductor layer SEL of the first transistor TFT1, for example.

The circuit array layer 140 may include the gate insulating layer 141 covering the semiconductor layer SEL, the inter-insulating layer 142 covering the gate electrode GE, the first planarization layer 143 covering the source electrode SE and the drain electrode DE, and the second planarization layer 144 covering the first planarization layer 143 and the anode connection electrodes ANDE.

The semiconductor layer SEL may include a silicon semiconductor such as polycrystalline silicon, monocrystalline silicon, low-temperature polycrystalline silicon, and amorphous silicon.

Each of the gate electrode GE, the source electrode SE, the drain electrode DE, and the anode connection electrode ANDE may be formed as a single layer or multiple layers including any one of molybdenum (Mo), aluminum (Al), chromium (Cr), gold (Au), titanium (Ti), nickel (Ni), neodymium (Nd) and copper (Cu) or any alloys thereof.

Each of the gate insulating layer 141 and the inter-insulating layer 142 may include or consist of an inorganic layer, e.g., a silicon nitride layer, a silicon oxynitride layer, a silicon oxide layer, a titanium oxide layer, or an aluminum oxide layer.

Each of the first planarization layer 143 and the second planarization layer 144 may include or consist of an organic layer such as acryl resin, epoxy resin, phenolic resin, polyamide resin, polyimide resin or the like.

Each of the pixel drivers PD of the circuit array layer 140 is connected to signal lines. The signal lines may include the scan line SL (refer to FIG. 3), the data line DL (refer to FIG. 3), the first power line ELVDL (refer to FIG. 3), and the second power line ELVSL (refer to FIG. 3). These signal lines may be connected to the pads SPD corresponding to the pad area PDA.

In an embodiment, the second power line ELVSL may be disposed in the non-display area NDA to surround the periphery of the display area DPA, for example. Accordingly, the second power line ELVSL may overlap at least one dam structure DAMS in a third direction DR3.

The second power line ELVSL may include a first wiring pattern layer VSLL1 disposed on the inter-insulating layer 142, and a second wiring pattern layer VSLL2 disposed on the first planarization layer 143 and connected to the first wiring pattern layer VSLL1.

In order to dispose the dam structure DAMS, the second planarization layer 144 may be disposed on a part of the second wiring pattern layer VSLL2.

The first planarization layer 143 may extend to the non-display area NDA to cover the first wiring pattern layer VSLL1.

The second planarization layer 144 may extend to the non-display area NDA to cover the second wiring pattern layer VSLL2 and the first planarization layer 143.

Two dam structures DAMS of the non-display area NDA may be provided to be spaced apart from each other.

The dam structure DAMS may be disposed on the second planarization layer 144.

Any one dam structure DAMS adjacent to the display area DPA may be disposed on the second planarization layer 144 covering a part of the second wiring pattern layer VSLL2.

Further, another dam structure DAMS adjacent to the edge of the substrate 110 may be disposed across the edge of the second planarization layer 144.

The encapsulation auxiliary structure ENAS may be closer to the edge of the substrate 110 than the dam structure DAMS is, and two or more encapsulation auxiliary structures ENAS may be provided to be spaced apart from each other.

The encapsulation auxiliary structure ENAS may be disposed on the inter-insulating layer 142 adjacent to the second planarization layer 144.

The bank buffer layer 121 and the first multilayer MTL1 are disposed between each of the dam structure DAMS and the encapsulation auxiliary structure ENAS and the substrate 110.

That is, the first multilayer MTL1 of the undercut structure is disposed under each of the dam structure DAMS and the encapsulation auxiliary structure ENAS, and the bank buffer layer 121 is disposed under the first multilayer MTL1.

The first multilayer MTL1 may include the first main layer MTL11 and the first cover layer MTL12.

Since the first cover layer MTL12 has a width greater than that of the first main layer MTL11, the edge of the first cover layer MTL12 protrudes beyond the first main layer MTL11. Accordingly, the first multilayer MTL1 may have an undercut structure.

The undercut structure of the first multilayer MTL1 may be provided by the galvanic corrosion effect of the first main layer MTL11. To this end, the first cover layer MTL12 may include or consist of a dissimilar metal material having a corrosion potential difference compared to the metal material of the first main layer MTL11.

In an embodiment, the first main layer MTL11 may include or consist of copper (Cu) or aluminum (Al), for example. In this case, the first cover layer MTL12 may include or consist of titanium (Ti) or molybdenum (Mo). That is, the first multilayer MTL1 may be formed as a double layer of any one of Ti/Cu, Mo/Cu, Ti/Al, and Mo/Al.

In addition, the first multilayer MTL1 may further include the first support layer MTL13 disposed between the bank buffer layer 121 and the first main layer MTL11 and including a metal material different from that of the first main layer MTL11.

In order to induce the galvanic corrosion effect of the first main layer MTL11, the first support layer MTL13 may include or consist of a dissimilar metal material having a corrosion potential difference compared to the metal material of the first main layer MTL11.

In an embodiment, when the first main layer MTL11 includes or consists of copper (Cu) or aluminum (Al), the first support layer MTL13 may include or consist of titanium (Ti) or molybdenum (Mo) similarly to the first cover layer MTL12, for example. That is, the first multilayer MTL1 may be formed as a triple layer of any one of Ti/Al/Ti, Ti/Cu/Ti, Mo/Al/Mo, and Mo/Cu/Mo.

In an alternative embodiment, the first cover layer MTL12 and the first support layer MTL13 may include or consist of different metal materials.

Since the bank buffer layer 121 is covered with the first support layer MTL13, in a process of deforming the first multilayer MTL1 into an undercut structure, damage to the bank buffer layer 121 disposed under the first multilayer MTL1 may be prevented.

The circuit array layer 140 may further include a crack preventing layer 145 adjacent to the edge of the substrate 110 and surrounding the edges of the gate insulating layer 141 and the inter-insulating layer 142. The crack preventing layer 145 may correspond to the region of the non-display area NDA except the pad area PDA and surround the encapsulation auxiliary structure ENAS.

The crack preventing layer 145 may include or consist of the same material as that of the first planarization layer 143 or the second planarization layer 144. In an alternative embodiment, the crack preventing layer 145 may include or consist of a separate inorganic insulating material. The crack preventing layer 145 may contact the substrate 110 through a hole penetrating the gate insulating layer 141 and the inter-insulating layer 142.

The plurality of anode electrodes AND respectively corresponding to the plurality of emission areas EA may be disposed on the second planarization layer 144, and may be respectively connected to the plurality of anode connection electrodes ANDE.

Each of the plurality of anode electrodes AND may include or consist of at least one low-resistance metal material of copper (Cu), silver (Ag), magnesium (Mg), aluminum (Al), platinum (Pt), lead (Pb), palladium (Pd), gold (Au), nickel (Ni), neodymium (Nd), iridium (Ir), chromium (Cr), lithium (Li), calcium (Ca), or any combinations thereof.

In an alternative embodiment, each of the plurality of anode electrodes AND may have a structure in which a conductive layer including a low-resistance metal material and a conductive layer including a transparent conductive material are stacked. In an embodiment, each of the plurality of anode electrodes AND may have a stacked structure of ITO/Mg, ITO/MgF, ITO/Ag, ITO/Ag/ITO, or the like.

The bank buffer layer 121 corresponding to the non-display area NEA is disposed on the second planarization layer 144, and covers the edges of the plurality of anode electrodes AND.

The bank buffer layer 121 may include or consist of at least one inorganic insulating material of silicon nitride, aluminum nitride, zirconium nitride, titanium nitride, hafnium nitride, tantalum nitride, silicon oxide, aluminum oxide, titanium oxide, tin oxide, or silicon oxynitride.

The bank buffer layer 121 may be disposed to have a thickness of about 1500 angstroms (Å) to about 2000 Å.

Due to the bank buffer layer 121 including an inorganic insulating material, the timing at which the cathode electrode CTD is exposed to outgas of the organic insulating material forming the first planarization layer 143 and the second planarization layer 144 of the circuit array layer 140 may be delayed. Accordingly, the oxidation of the cathode electrode CTD may be delayed, which makes it possible to suppress the reduction in the lifetime of the display device 100.

The bank buffer layer 121 may be spaced apart from the edges of the plurality of anode electrodes AND in the third direction DR3. That is, the bank buffer layer 121 may cover the edges of the plurality of anode electrodes AND in the form of eaves.

In an embodiment, the bank buffer layer 121 may be disposed in an undercut structure including an edge protruding beyond a sacrificial layer SCL remaining on the plurality of anode electrodes AND, for example.

The second multilayer MTL2 disposed on the bank buffer layer 121 may be electrically insulated from the plurality of anode electrodes AND by the bank buffer layer 121.

The second multilayer MTL2 is disposed between the bank buffer layer 121 and the pixel defining layer 122 and has an undercut structure.

The second multilayer MTL2 may include the second main layer MTL21 and the second cover layer MTL22.

Since the second cover layer MTL22 has a width greater than that of the second main layer MTL21, the edge of the second cover layer MTL22 protrudes beyond the second main layer MTL21. Accordingly, the second multilayer MTL2 may have an undercut structure.

The undercut structure of the second multilayer MTL2 may be provided by the galvanic corrosion effect of the second main layer MTL21. To this end, the second cover layer MTL22 may include or consist of a dissimilar metal material having a corrosion potential difference compared to the metal material of the second main layer MTL21.

In an embodiment, the second main layer MTL21 may include or consist of copper (Cu) or aluminum (Al), for example. In this case, the second cover layer MTL22 may include or consist of titanium (Ti) or molybdenum (Mo). That is, the second multilayer MTL2 may be formed as a double layer of any one of Ti/Cu, Mo/Cu, Ti/Al, and Mo/Al.

In addition, the second multilayer MTL2 may further include the second support layer MTL23 disposed between the bank buffer layer 121 and the second main layer MTL21 and including a metal material different from that of the second main layer MTL21.

In order to induce the galvanic corrosion effect of the second main layer MTL21, the second support layer MTL23 may include or consist of a dissimilar metal material having a corrosion potential difference compared to the metal material of the second main layer MTL21.

In an embodiment, when the second main layer MTL21 includes or consists of copper (Cu) or aluminum (Al), the second support layer MTL23 may include or consist of titanium (Ti) or molybdenum (Mo) similarly to the second cover layer MTL22, for example. That is, the second multilayer MTL2 may be formed as a triple layer of any one of Ti/Al/Ti, Ti/Cu/Ti, Mo/Al/Mo, and Mo/Cu/Mo.

In an alternative embodiment, the second cover layer MTL22 and the second support layer MTL23 may include or consist of different metal materials.

Since the bank buffer layer 121 is covered with the second support layer MTL23, in a process of deforming the second multilayer MTL2 into an undercut structure, damage to the bank buffer layer 121 disposed under the second multilayer MTL2 may be prevented.

The second multilayer MTL2 and the first multilayer MTL1 are formed in the same layer and have the same structure.

The pixel defining layer 122 disposed on the second multilayer MTL2 may include or consist of an organic insulating material. In an embodiment, the pixel defining layer 122 may include or consist of at least one of acrylic resin, epoxy resin, phenolic resin, polyamide resin, polyimide rein, unsaturated polyester resin, polyphenylene resin, polyphenylenesulfide resin, or benzocyclobutene (“BCB”), for example.

The pixel defining layer 122 may be formed in the same layer as the encapsulation auxiliary structure ENAS and the dam structure DAMS of the non-display area NDA.

The spacers SPC (refer to FIG. 2) corresponding to a part of the non-emission area NEA and spaced apart from each other may be disposed on a part of the pixel defining layer 122 and the dam structure DAMS. The spacer SPC may have a width smaller than those of the pixel defining layer 122 and the dam structure DAMS, and may include or consist of the same material as those of the pixel defining layer 122 and the dam structure DAMS. In an embodiment, the spacer SPC, the pixel defining layer 122, the dam structure DAMS, and the encapsulation auxiliary structure ENAS may be provided together by a patterning process using a halftone mask, for example.

The first common layer CML1 is disposed on the plurality of anode electrodes AND and the pixel defining layer 122.

In an embodiment, the first common layer CML1 corresponds to the entirety of the area of the substrate 110 except the pad area PDA.

Accordingly, in the display area DPA, the first common layer CML1 covers the plurality of anode electrodes AND and the pixel defining layer 122. Further, in the non-display area NDA, the first common layer CML1 covers the dam structure DAMS and the encapsulation auxiliary structure ENAS.

As shown in FIG. 5, the first common layer CML11 on the plurality of anode electrodes AND is separated from the first common layer CML12 on the pixel defining layer 122 by the undercut structure of the second multilayer MTL2.

Further, as shown in FIG. 6, the first common layer CML13 disposed on each of the dam structure DAMS and the encapsulation auxiliary structure ENAS is separated from the first common layer CML14 disposed around each of the dam structure DAMS and the encapsulation auxiliary structures ENAS by the undercut structure of the first multilayer MTL1.

Accordingly, even when the first common layer CML1 is deposited on the entirety of the surface without a mask, it is separated by the first multilayer MTL1 and the second multilayer MTL2, so that the leakage current through the first common layer CML1 may be prevented.

The first common layer CML1 may include a hole transporting layer, or may include a hole transporting layer and a hole injecting layer.

The plurality of light-emitting layers EML respectively corresponds to the plurality of emission areas EA, and is respectively disposed on the plurality of first common layers CML1. The plurality of light-emitting layers EML may include the first light-emitting layer EML1 corresponding to the first emission area EA1, the second light-emitting layer EML2 corresponding to the second emission area EA2, and the third light-emitting layer EML3 corresponding to the third emission area EA3.

The first light-emitting layer EML1, the second light-emitting layer EML2, and the third light-emitting layer EML3 may include or consist of dopant materials or host materials corresponding to different colors to emit lights of different colors.

The second common layer CML2 is disposed on the first common layer CML1 and covers the plurality of light-emitting layers EML.

In an embodiment, the second common layer CML2 corresponds to the entirety of the area of the substrate 110 except the pad area PDA.

Accordingly, in the display area DPA, the second common layer CML2 covers the plurality of anode electrodes AND and the pixel defining layer 122. Further, in the non-display area NDA, the second common layer CML2 covers the dam structure DAMS and the encapsulation auxiliary structure ENAS.

As shown in FIG. 5, the second common layer CML21 on the plurality of anode electrodes AND is separated from the second common layer CML22 on the pixel defining layer 122 by the undercut structure of the second multilayer MTL2.

Further, as shown in FIG. 6, the second common layer CML23 disposed on each of the dam structure DAMS and the encapsulation auxiliary structure ENAS is separated from the second common layer CML24 disposed around each of the dam structure DAMS and the encapsulation auxiliary structures ENAS by the undercut structure of the first multilayer MTL1.

Accordingly, even when the second common layer CML2 is deposited on the entirety of the surface without a mask, it is separated by the first multilayer MTL1 and the second multilayer MTL2, so that the leakage current through the second common layer CML2 may be prevented.

The second common layer CML2 may include an electron transporting layer, or may include an electron transporting layer and an electron injecting layer.

The cathode electrode CTD corresponds to the plurality of emission areas EA and is disposed on the second common layer CML2. The cathode electrode CTD may include a transparent metal oxide material such as indium tin oxide (“ITO”), indium zinc oxide (“IZO”), and indium gallium zinc oxide (“IGZO”).

In an embodiment, the cathode electrode CTD corresponds to the entirety of the area of the substrate 110 except the pad area PDA.

Accordingly, in the display area DPA, the cathode electrode CTD covers the plurality of anode electrodes AND and the pixel defining layer 122. Further, in the non-display area NDA, the cathode electrode CTD covers the dam structure DAMS and the encapsulation auxiliary structure ENAS.

As shown in FIG. 5, the cathode electrode CTD1 on the plurality of anode electrodes AND is separated from the cathode electrode CTD2 on the pixel defining layer 122 by the undercut structure of the second multilayer MTL2.

Instead, the cathode electrodes CTD1 on the plurality of anode electrodes AND are electrically connected to each other through the second multilayer MTL2.

Further, as shown in FIG. 6, the cathode electrode CTD3 disposed on each of the dam structure DAMS and the encapsulation auxiliary structure ENAS is separated from the cathode electrode CTD4 disposed around each of the dam structure DAMS and the encapsulation auxiliary structures ENAS by the undercut structure of the first multilayer MTL1.

The undercut structure of each of the first multilayer MTL1 and the second multilayer MTL2 is used to separate the first common layer CML1, the second common layer CML2, and the cathode electrode CTD under each of the pixel defining layer 122, the dam structure DAMS, and the encapsulation auxiliary structure ENAS.

Accordingly, in the first multilayer MTL1, the width of the eaves in which the edge of the first cover layer MTL12 protrudes beyond the first main layer MTL11 may be selected within a range of about 0.3 micrometer (μm) to about 0.7 μm.

Similarly, in the second multilayer MTL2, the width of the eaves in which the edge of the second cover layer MTL22 protrudes beyond the second main layer MTL21 may be selected within a range of about 0.3 μm to about 0.7 μm.

When the width of the eaves according to the undercut structure is smaller than about 0.3 μm, the separation of the first common layer CML1, the second common layer CML2, and the cathode electrode CTD may not be implemented.

Further, when the width of the eaves according to the undercut structure is greater than about 0.7 μm, the supporting force of the first cover layer MTL12 and the second cover layer MTL22 becomes weak and, thus, the shape of the eaves may be easily damaged.

In addition, in order to maintain the shape of the eaves, each of the first cover layer MTL12 and the second cover layer MTL22 may have a thickness of about 700 Å or more. However, this is only one of embodiments, and the thickness of the first cover layer MTL12 and the second cover layer MTL22 may be changed depending on the material and the protruding width.

Further, each of the first main layer MTL11 of the first multilayer MTL1 and the second main layer MTL21 of the second multilayer MTL2 may have the thickness greater than the sum of the thickness of the second common layer CML2 and the thickness of the cathode electrode CTD in order to be bonded to the first encapsulation layer 131. In an alternative embodiment, the total thickness of the first support layer MTL13 and the first main layer MTL11 of the first multilayer MTL1 and the total thickness of the second support layer MTL23 and the second main layer MTL21 of the second multilayer MTL2 may be greater than the sum of the thickness of the first common layer CML1, the thickness of the light-emitting layer EML, the thickness of the second common layer CML2, and the thickness of the cathode electrode CTD.

As described above, due to the undercut structure of each of the first multilayer MTL1 and the second multilayer MTL2, the first common layer CML1, the second common layer CML2, and the cathode electrode CTD are separated under each of the pixel defining layer 122, the dam structure DAMS, and the encapsulation auxiliary structure ENAS, so that it is possible to prevent the leakage current between adjacent emission areas. Accordingly, the deterioration of display quality such as color purity, a contrast ratio, or the like by the leakage current may be prevented.

Further, a mask for each of the plurality of emission areas EA is not desired, so that the disposition process may be further facilitated.

In order to prevent permeation of moisture or oxygen into the light-emitting layer EML, the light-emitting array layer 120 is covered with the encapsulation structure 130.

The encapsulation structure 130 may have a structure in which an inorganic layer and an organic layer are alternately stacked. The organic layer of the encapsulation structure 130 may have a relatively large thickness to protect the light-emitting array layer 120 and the circuit array layer 140 from scratches by foreign substances or the like. Further, the inorganic layer of the encapsulation structure 130 may encapsulate the organic layer to block permeation of moisture or oxygen through the organic layer.

In an embodiment, the encapsulation structure 130 may include the first encapsulation layer 131 disposed on the cathode electrode CTD of the light-emitting array layer 120 and including an inorganic insulating material, the second encapsulation layer 132 disposed on the first encapsulation layer 131 and including an organic insulating material, and the third encapsulation layer 133 disposed on the first encapsulation layer 131 and covering the second encapsulation layer 132 and including an inorganic insulating material, for example.

Further, in an embodiment, each of the first encapsulation layer 131 and the third encapsulation layer 133 corresponds to the entirety of the area of the substrate 110 except the pad area PDA, similarly to the first common layer CML1, the second common layer CML2, and the cathode electrode CTD.

In an embodiment, the first encapsulation layer 131 and the third encapsulation layer 133 may include or consist of multiple layers in which one or more inorganic layers of a silicon nitride layer, a silicon oxynitride layer, a silicon oxide layer, a titanium oxide layer and an aluminum oxide layer are alternately stacked, for example.

The first encapsulation layer 131 may include or consist of an inorganic insulating material stacked by a chemical vapor deposition (“CVD”) method. Accordingly, the first encapsulation layer 131 may be bonded to each of the first main layer MTL11 of the first multilayer MTL1 and the second main layer MTL21 of the second multilayer MTL2.

The first main layer MTL11 and the second main layer MTL21 contact the first common layer CML1, the second common layer CML2, and the cathode electrode CTD corresponding to the display area DPA, and are bonded to the first encapsulation layer 131 on the cathode electrode CTD. To this end, the thickness of the first main layer MTL11 and the thickness of the second main layer MTL21 may be selected within a range exceeding the sum of the thickness of the first common layer CML1, the thickness of the second common layer CML2, and the thickness of the cathode electrode CTD.

Since the first encapsulation layer 131 is bonded to the first main layer MTL11 of the first multilayer MTL1 disposed under each of the dam structure DAMS and the encapsulation auxiliary structure ENAS, even when the organic material of the non-display area NDA is not completely removed, an encapsulation structure including bonding between inorganic materials may be provided.

That is, even when the first encapsulation layer 131 overlaps the first common layer CML1 and the second common layer CML2 disposed in the non-display area NDA, the first encapsulation layer 131 is bonded to the first multilayer MTL1, so that an encapsulation structure formed by bonding between inorganic materials may be provided. That is, it is not desired to dispose the first common layer CML1 and the second common layer CML2 to have a width smaller than that of the first encapsulation layer 131 in order to provide the encapsulation structure formed by bonding between inorganic materials. Therefore, even when the first common layer CML1 and the second common layer CML2 are stacked without a mask, a separate etching process for removing the first common layer CML1 and the second common layer CML2 may be omitted. Therefore, the fabricating process of the display device 100 may be relatively simplified and facilitated.

Further, since the first encapsulation layer 131 is bonded to the second main layer MTL21 of the second multilayer MTL2 disposed under the pixel defining layer 122, the plurality of light-emitting layers EML corresponding to the plurality of emission areas EA may be individually encapsulated. Accordingly, the expansion of deterioration caused by oxygen or moisture to neighboring emission areas EA may be prevented.

The second encapsulation layer 132 includes or consists of an organic insulating material.

In an embodiment, the second encapsulation layer 132 may include or consist of at least one of acrylic resin, epoxy resin, phenolic resin, polyamide resin, or polyimide resin, for example.

In an alternative embodiment, in order to prevent damage to the organic material such as the first common layer CML1, the light-emitting layer EML, and the second common layer CML2 at the time of disposing the second encapsulation layer 132, the second encapsulation layer 132 may include or consist of a low-temperature curable organic layer that may be cured by low-temperature heat or light. In an embodiment, the second encapsulation layer 132 may include or consist of a negative photoresist material including acrylic resin, monomer acrylate photo initiator cross linker surfactant, or the like, for example.

The second encapsulation layer 132 may be formed by a process of spreading a liquid or gel-type organic material dropped on the first encapsulation layer 131 in the area defined by the dam structure DAMS, and then curing the spread organic material.

Accordingly, the second encapsulation layer 132 may be disposed in the region surrounded by the dam structure DAMS.

The third encapsulation layer 133 may include or consist of an inorganic insulating material, and may be bonded to the first encapsulation layer 131 at a part of the vicinity of the dam structure DAMS in the non-display area NDA while covering the second encapsulation layer 132.

Further, as illustrated in FIG. 5, the first encapsulation layer 131 and the third encapsulation layer 133 of the encapsulation structure 130 may correspond to the entirety of the surface of the substrate 110 except the pad area PDA.

As described above, the display device 100 in an embodiment includes the encapsulation auxiliary structure ENAS and the first and second multilayers MTL1 and MTL2, and thus may include an encapsulation structure formed by bonding between inorganic materials while disposing the first common layer CML1, the second common layer CML2, the cathode electrode CTD, the first encapsulation layer 131, and the third encapsulation layer 133 corresponding to the entirety of the surface of the substrate 110 except the pad area PDA.

Accordingly, it may be advantageous to facilitate and simplify of the fabricating process without deteriorating the reliability of the encapsulation structure for preventing permeation of oxygen or moisture.

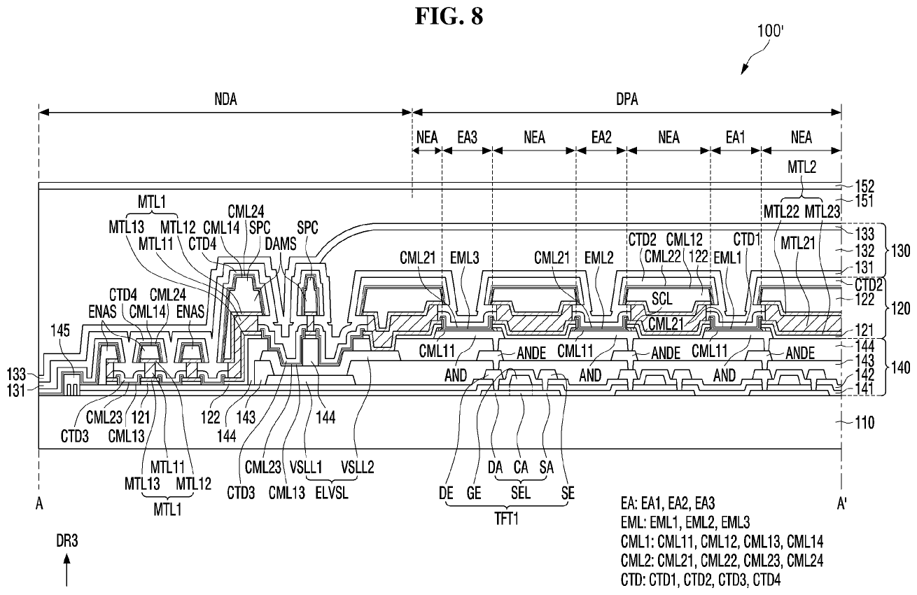

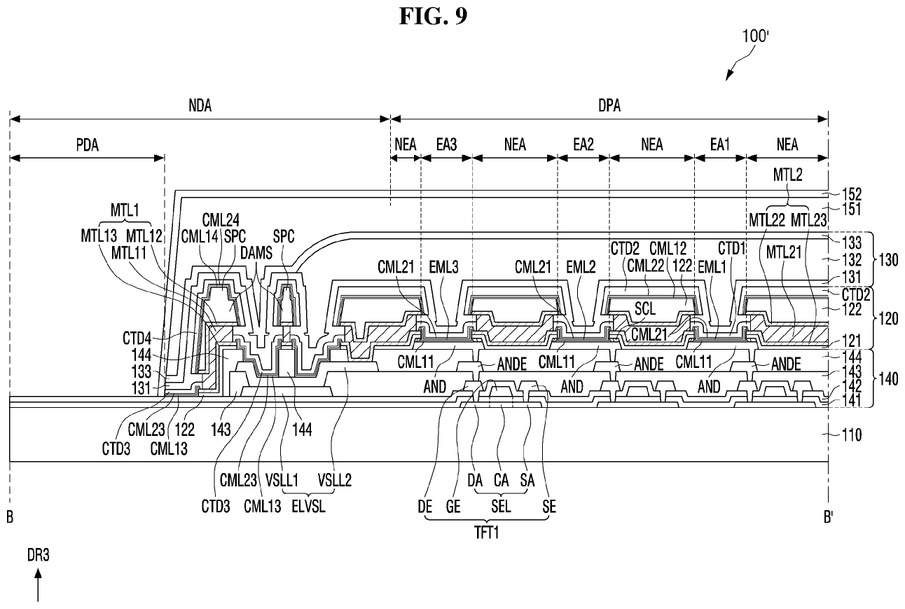

FIG. 8 is a cross-sectional view illustrating an embodiment of a surface taken along line A-A′ of FIG. 1 in a display device. FIG. 9 is a cross-sectional view illustrating an embodiment of a surface taken along line B-B′ of FIG. 1 in a display device.

A display device 100′ in another embodiment may further include a touch sensing unit (not shown) for a touch sensing function as well as the light-emitting array layer 120 for a display function. In this case, the touch sensing unit may be disposed on the encapsulation structure 130 to be closer to a display surface in order to improve accuracy in sensing a user's touch.

Further, when the touch sensing unit is of a capacitance type, in order to improve reliability of touch sensing, it is desired that the touch sensing unit is spaced apart from a surface on which a user's contact is sensed by a relatively uniform distance. That is, the touch sensing unit needs to be supported on a flat surface.

Accordingly, referring to FIGS. 8 and 9, the display device 100′ in another embodiment is the same as the embodiment shown in FIGS. 1 to 7 except that it further includes a planarization auxiliary layer 151 for flatly supporting a touch sensing unit and a touch unit support layer 152 for increasing the adhesive strength between the planarization auxiliary layer 151 and the touch sensing unit, so that redundant description will be omitted in the following description.

The planarization auxiliary layer 151 may be flatly disposed on the encapsulation structure 130 and may include or consist of an organic insulating material.

The planarization auxiliary layer 151 corresponds to the display area DPA and the dam structure DAMS and the encapsulation auxiliary structure ENAS of the non-display area NDA, and flatly covers the dam structure DAMS and the encapsulation auxiliary structure ENAS.

Since the pads of the pad area PDA are exposed to be connected to an external circuit board, the planarization auxiliary layer 151 is not disposed on the pad area PDA.

Thus, the planarization auxiliary layer 151 may include or consist of a material that may be relatively easily patterned to prevent damage to the light-emitting array layer 120 or the like. In an embodiment, the planarization auxiliary layer 151 may include or consist of a negative photoresist material including acrylic resin, monomer acrylate photo initiator cross linker surfactant, or the like, for example.

The touch unit support layer 152 is disposed on the substrate 110, and includes or consists of an inorganic insulating material, and covers the planarization auxiliary layer 151.

In an embodiment, the touch unit support layer 152 may include or consist of multiple layers in which one or more inorganic layers of a silicon nitride layer, a silicon oxynitride layer, a silicon oxide layer, a titanium oxide layer and an aluminum oxide layer are alternately stacked, for example.

Next, a method of fabricating a display device in an embodiment will be described.

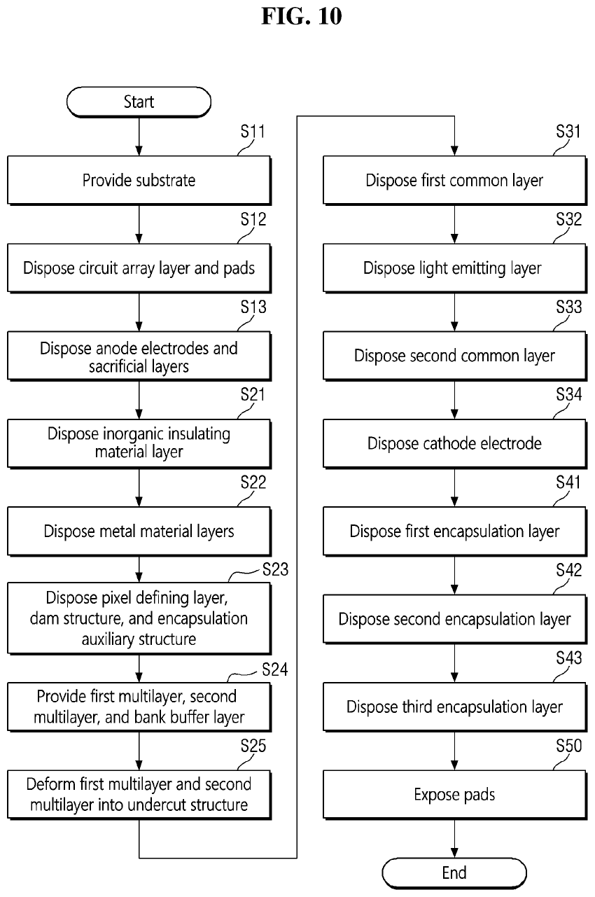

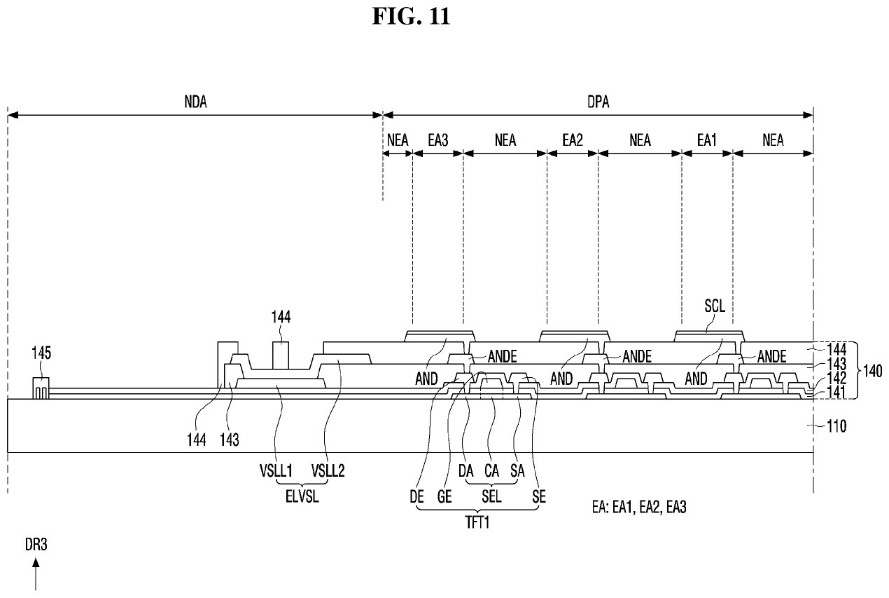

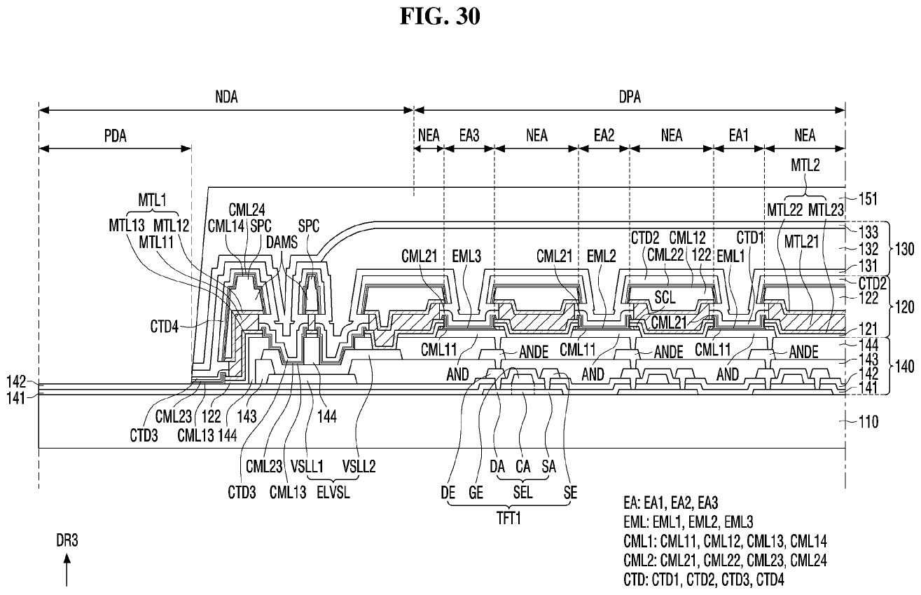

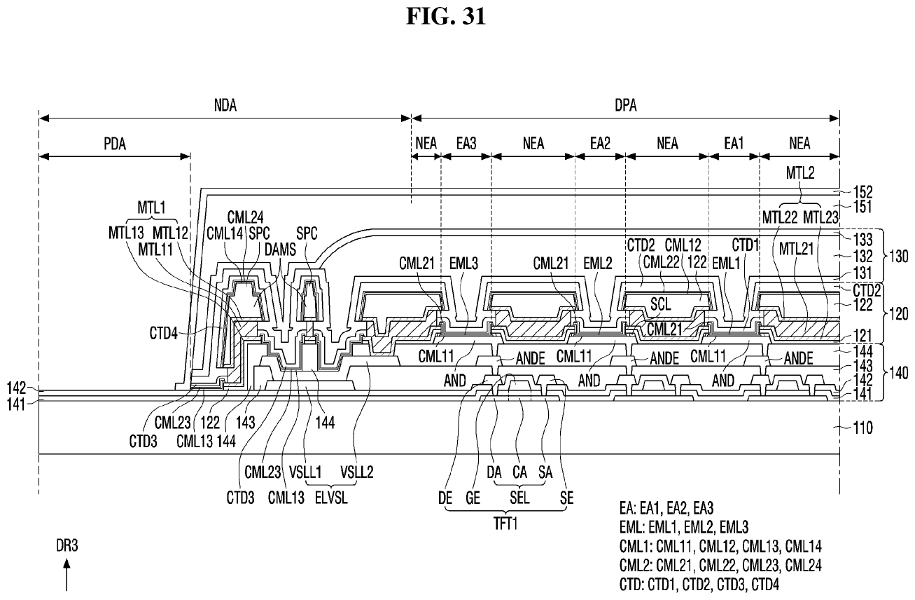

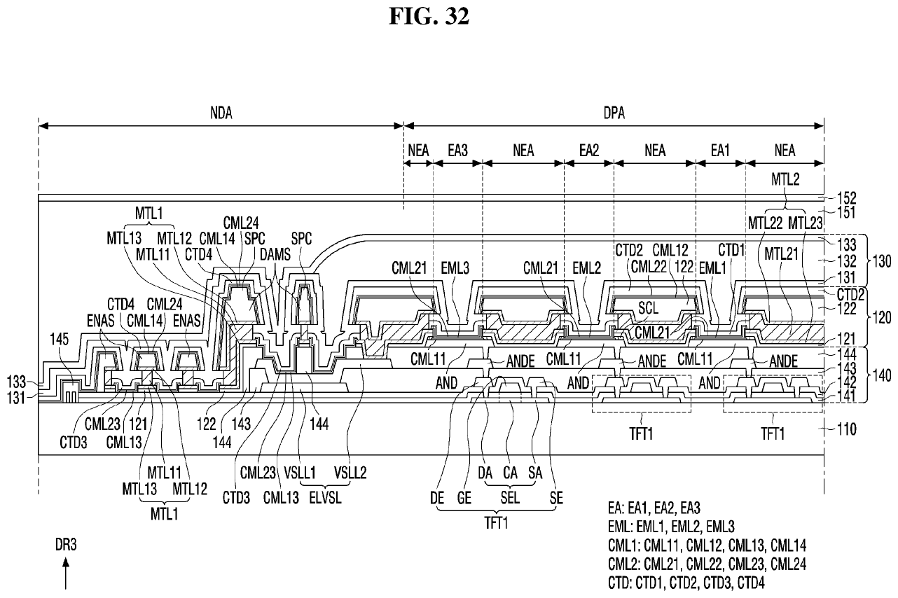

FIG. 10 is a flowchart illustrating a method of fabricating the display device. FIGS. 11 to 29 are process views illustrating some operations of FIG. 10. FIGS. 30 to 32 are process views illustrating some operations of a method of fabricating a display device.

Referring to FIG. 10, a method of fabricating the display device 100 in an embodiment includes providing the substrate 110 including the display area DPA in which the plurality of emission areas EA is arranged to display an image and the non-display area NDA disposed around the display area DPA (operation S11), disposing the circuit array layer 140 on the substrate 110, the circuit array layer including the plurality of pixel drivers PD respectively corresponding to the plurality of emission areas EA, and the pads SPD in the pad area PDA which is a part of the non-display area NDA (operation S12), disposing the plurality of anode electrodes AND respectively corresponding to the plurality of emission areas EA and the plurality of sacrificial layers SCL respectively stacked on the plurality of anode electrodes AND on the circuit array layer 140 (operation S13), disposing an inorganic insulating material layer covering the plurality of sacrificial layers SCL on the circuit array layer 140 (operation S21), disposing two or more different metal material layers on the inorganic insulating material layer (operation S22), disposing the pixel defining layer 122 corresponding to the non-emission area NEA which is a separation region between the plurality of emission areas EA, the dam structure DAMS corresponding to the non-display area NDA and surrounding the edge of the display area DPA, and the encapsulation auxiliary structure ENAS corresponding to the region of the non-display area NDA except the pad area PDA, surrounding a part of the edge of the display area DPA, and disposed between the dam structure DAMS and the edge of the substrate 110 on the metal material layers (operation S23), patterning metal material layers and an inorganic insulating material layer using the pixel defining layer 122, the dam structure DAMS, and the encapsulation auxiliary structure ENAS as a mask, providing the first multilayer MTL1 including the metal material layers remaining under each of the dam structure DAMS and the encapsulation auxiliary structure ENAS, providing the second multilayer MTL2 including the metal material layers remaining under the pixel defining layer 122, and providing the bank buffer layer 121 including the inorganic insulating material layer remaining under each of the first multilayer MTL1 and the second multilayer MTL2 (operation S24), deforming the first multilayer MTL1 and the second multilayer MTL2 into an undercut structure, and patterning the plurality of sacrificial layers SCL to expose the plurality of anode electrodes AND (operation S25), disposing the first common layer CML1 corresponding to the entirety of the area of the substrate 110 on the plurality of anode electrodes AND, the pixel defining layer 122, the dam structure DAMS, and the encapsulation auxiliary structure ENAS (operation S31), disposing the plurality of light-emitting layers EML respectively corresponding to the plurality of emission areas EA on the first common layer CML1 (operation S32), disposing the second common layer CML2 corresponding to the entirety of the area of the substrate 110 and covering the plurality of light-emitting layers EML on the first common layer CML1 (operation S33), disposing the cathode electrode CTD corresponding to the entirety of the area of the substrate 110 on the second common layer CML2 (operation S34), disposing the first encapsulation layer 131 corresponding to the entirety of the area of the substrate 110 on the cathode electrode CTD (operation S41), disposing the second encapsulation layer 132 corresponding to the region surrounded by the dam structure DAMS on the first encapsulation layer 131 (operation S42), disposing the third encapsulation layer 133 corresponding to the entirety of the area of the substrate 110 and covering the second encapsulation layer 132 on the first encapsulation layer 131 (operation S43), and removing a part of each of the first common layer CML1, the second common layer CML2, the cathode electrode CTD, the first encapsulation layer 131, and the third encapsulation layer 133 corresponding to the pad area PDA, and exposing the pads SPD (operation S50).

Referring to FIG. 11, the substrate 110 including the display area DPA and the non-display area NDA may be provided (operation S11), the circuit array layer 140 and the pads SPD may be disposed on the substrate 110 (operation S12), and the plurality of anode electrodes AND and the plurality of sacrificial layers SCL may be disposed on the circuit array layer 140 (operation S13).

As shown in FIG. 1, the display area DPA of the substrate 110 includes the plurality of emission areas EA arranged in the first direction DR1 and the second direction DR2 and the non-emission area NEA which is a separation region between the plurality of emission areas EA.

The non-display area NDA of the substrate 110 may include the pad area PDA disposed side by side with at least one edge (e.g., the lower edge of FIG. 1) of the display area DPA.

The circuit array layer 140 may include the plurality of pixel drivers PD respectively corresponding to the plurality of emission areas EA, and various signal lines connected to the plurality of pixel drivers PD.

As shown in FIG. 3, each of the plurality of pixel drivers PD may include the first transistor TFT1 connected to the anode electrode AND, and the second transistor TFT2 connected to the gate electrode of the first transistor TFT1.

The first transistor TFT1 of each of the plurality of emission areas EA may include the semiconductor layer SEL disposed on the substrate 110, the gate electrode GE disposed on the gate insulating layer 141 covering the semiconductor layer SEL, and the source electrode SE and the drain electrode DE disposed on the inter-insulating layer 142 covering the gate electrode GE.

As illustrated in FIG. 11, the circuit array layer 140 may further include the first planarization layer 143 covering the source electrode SE and the drain electrode DE, and the second planarization layer 144 covering the anode connection electrodes ANDE on the first planarization layer 143.

The circuit array layer 140 may further include the crack preventing layer 145 adjacent to the edge of the substrate 110 and surrounding the edges of the gate insulating layer 141 and the inter-insulating layer 142.

Among the signal lines of the circuit array layer 140, the second power line ELVSL connected to the cathode electrode CTD of the light-emitting element EMD may be disposed in the non-display area NDA and may surround the periphery of the display area DPA. Further, the second power line ELVSL may include the first wiring pattern layer VSLL1 on the inter-insulating layer 142 and the second wiring pattern layer VSLL2 on the first planarization layer 143.

The second wiring pattern layer VSLL2 may be electrically connected to the first wiring pattern layer VSLL1 through the hole penetrating the first planarization layer 143.

Further, opposite ends of the second wiring pattern layer VSLL2 in a width direction may be covered with the second planarization layer 144. That is, the central portion of the second wiring pattern layer VSLL2 in the width direction may be exposed without being covered with the second planarization layer 144.

The first planarization layer 143 may be disposed across the region of the non-display area NDA corresponding to the first wiring pattern layer VSLL1 as well as the display area DPA.

In an embodiment, the first planarization layer 143 may be formed by a process of removing a part of the organic insulating material layer applied onto the inter-insulating layer 142 that is disposed between the edges of the substrate 110 in the vicinity of the first wiring pattern layer VSLL1, for example. In this case, the hole corresponding to a part of the first wiring pattern layer VSLL1 and penetrating the first planarization layer 143 may be provided together.

The second planarization layer 144 may be disposed across the region corresponding to the first planarization layer 143 and the second wiring pattern layer VSLL2 as well as the display area DPA.

In an embodiment, the second planarization layer 144 may be formed by a process of removing a part of the organic insulating material layer applied onto the first planarization layer 143 that is disposed between the edges of the substrate 110 in the vicinity of the second wiring pattern layer VSLL2 and the first planarization layer 143, for example. In this case, the hole corresponding to a part of the second wiring pattern layer VSLL2 and penetrating the second planarization layer 144 may be provided together.

As illustrated in FIG. 1, the pads SPD connected to a circuit board may be disposed in the pad area PDA which is a part of the non-display area NDA and disposed side by side with one edge of the substrate 110.

Although not shown in detail, each of the pads SPD may include at least one of a first pad layer disposed on the gate insulating layer 141 and including the same material as that of the gate electrode GE, and a second pad layer disposed on the inter-insulating layer 142 and including the same material as those of the source electrode SE and the drain electrode DE.

Although not shown in detail, the circuit board may include at least one of an integrated circuit chip of a display driving circuit for driving the data line DL, or a power supply circuit for supplying various voltages or powers. In addition, when the display device 100′ includes the touch sensing unit as in another embodiment, the circuit board may further include an integrated circuit chip of a touch driving circuit for driving the touch sensing unit. However, this is only one of embodiments, and the circuit board according to this specification is not limited to the above description.

The plurality of anode electrodes AND respectively corresponding to the plurality of emission areas EA may be disposed on the circuit array layer 140, and the plurality of sacrificial layers SCL may be respectively disposed on the plurality of anode electrodes AND.

Each of the plurality of anode electrodes AND may include or consist of at least one low-resistance metal material of copper (Cu), silver (Ag), magnesium (Mg), aluminum (Al), platinum (Pt), lead (Pb), palladium (Pd), gold (Au), nickel (Ni), neodymium (Nd), iridium (Ir), chromium (Cr), lithium (Li), calcium (Ca), or any combinations thereof.

In an alternative embodiment, each of the plurality of anode electrodes AND may have a structure in which a conductive layer including a low-resistance metal material and a conductive layer including a transparent conductive material are stacked. In an embodiment, each of the plurality of anode electrodes AND may have a stacked structure of ITO/Mg, ITO/MgF, ITO/Ag, ITO/Ag/ITO, or the like, for example.

Each of the plurality of sacrificial layers SCL may include or consist of at least one metal oxide of indium gallium zinc oxide (“IGZO”), indium tin zinc oxide (“ITZO”), or indium zinc oxide (“IZO”). The sacrificial layer SCL may have a thickness smaller than those of the anode electrode AND and the bank buffer layer 121. In an embodiment, the sacrificial layer SCL may have a thickness of about 500 Å, for example.

In an embodiment, operation S13 of disposing the plurality of anode electrodes AND and the plurality of sacrificial layers SCL may include a process of sequentially disposing a conductive material layer for disposing the anode electrode AND and a metal oxide material layer for disposing the sacrificial layer SCL on the second planarization layer 144 of the circuit array layer 140, and a process of simultaneously patterning the conductive material layer and the metal oxide material layer on the second planarization layer 144 in a state where a mask defining openings corresponding to the plurality of emission areas EA is disposed on the metal oxide material layer to remove a part of each of the conductive material layer and the metal oxide material layer corresponding to the non-emission area NEA, for example.

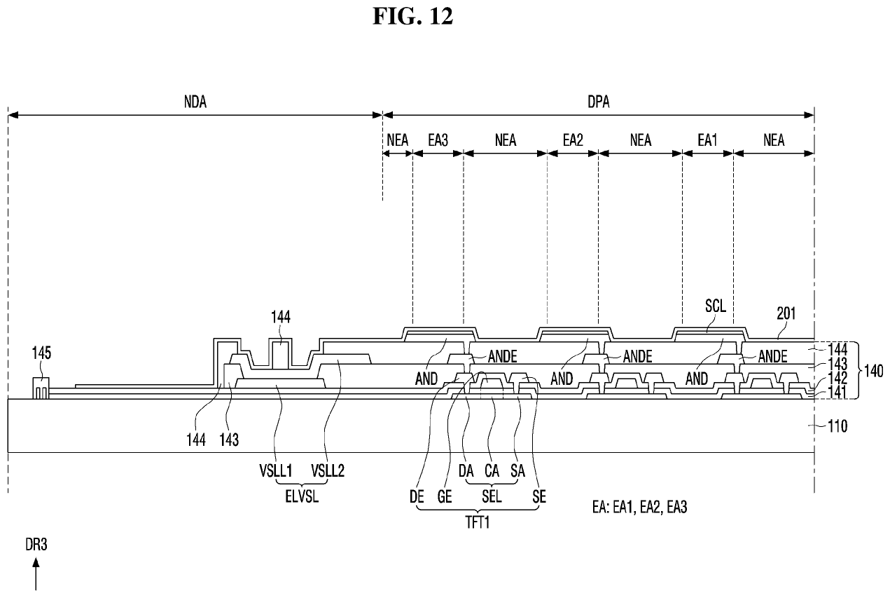

Next, referring to FIG. 12, an inorganic insulating material layer 201 covering the plurality of sacrificial layers SCL is disposed on the second planarization layer 144 of the circuit array layer 140 (operation S21).

The inorganic insulating material layer 201 may be entirely disposed in the area of the substrate 110 except the pad area PDA and the edge area of the substrate 110. To this end, operation S21 of disposing the inorganic insulating material layer 201 may include a process of stacking an inorganic insulating material in a state where the mask covering the pad area PDA and the edge area of the substrate is disposed.

The inorganic insulating material layer 201 may be disposed on the second planarization layer 144 in the display area DPA, and may be disposed on the second planarization layer 144 or the inter-insulating layer 142 in the non-display area NDA. Further, the inorganic insulating material layer 201 may cover the second wiring pattern layer VSLL2 in the non-display area NDA.

The inorganic insulating material layer 201 may include or consist of at least one inorganic insulating material of silicon nitride, aluminum nitride, zirconium nitride, titanium nitride, hafnium nitride, tantalum nitride, silicon oxide, aluminum oxide, titanium oxide, tin oxide, or silicon oxynitride.

The inorganic insulating material layer 201 may be disposed to have a thickness of about 1500 Å to about 2000 Å.

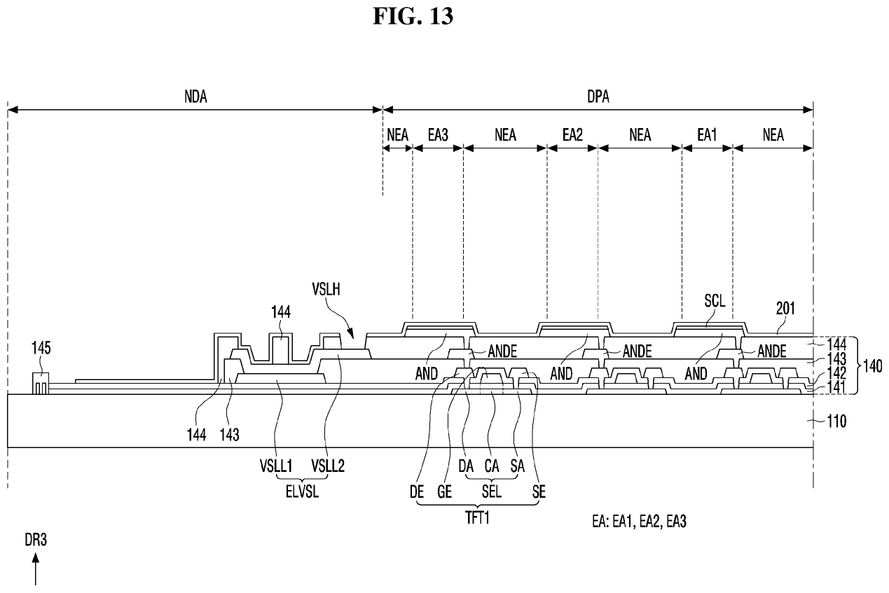

Referring to FIG. 13, after the inorganic insulating material layer 201 is disposed, a second power line contact hole VSLH corresponding to at least a part of the second wiring pattern layer VSLL2 and penetrating the inorganic insulating material layer 201 and the second planarization layer 144 may be defined.

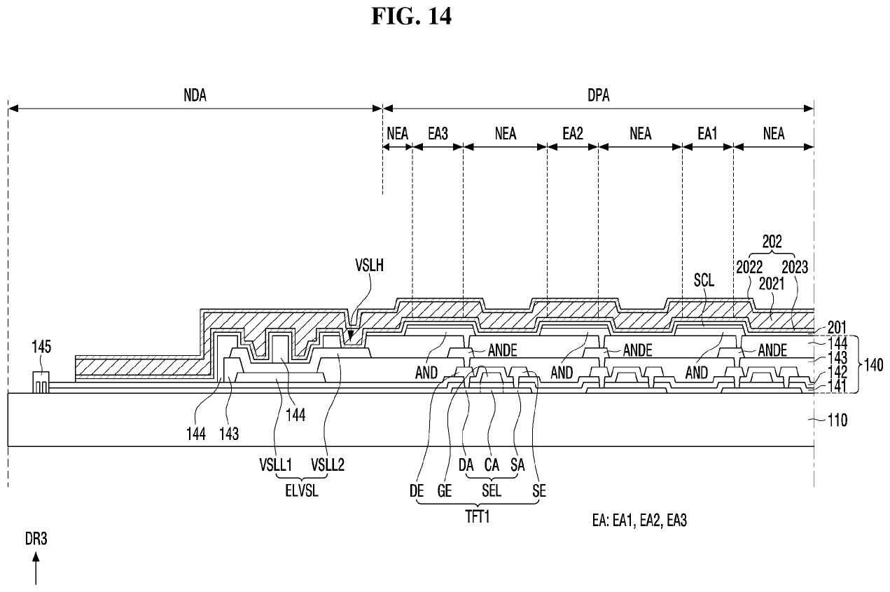

Referring to FIG. 14, two or more different metal material layers 202 are disposed on the inorganic insulating material layer 201 (operation S22).

The two or more different metal material layers 202 may include a first metal material layer 2021 including a predetermined metal material, and a second metal material layer 2022 disposed on the first metal material layer 2021 and including a metal material different from that of the first metal material layer 2021.

The second metal material layer 2022 may include or consist of a dissimilar metal material having a corrosion potential difference compared to the metal material of the first metal material layer 2021. In an embodiment, the first metal material layer 2021 may include or consist of copper (Cu) or aluminum (Al), and the second metal material layer 2022 may include or consist of titanium (Ti) or molybdenum (Mo), for example.

In order to maintain the undercut structure of each of the first multilayer MTL1 and the second multilayer MTL2 including or consisting of two or more different metal material layers 202, the second metal material layer 2022 may have a thickness of about 700 Å or more.

Further, for adhesion between each of the first multilayer MTL1 and the second multilayer MTL2 and the first encapsulation layer 131, the first metal material layer 2021 may have a relatively large thickness. In an embodiment, the first metal material layer 2021 may have a thickness exceeding the sum of the thickness of the second common layer CML2 and the thickness of the cathode electrode CTD, for example. In another embodiment the first metal material layer 2021 may have a thickness exceeding the sum of the thickness of the first common layer CML1, the thickness of the light-emitting layer EML, the thickness of the second common layer CML2, and the thickness of the cathode electrode CTD.

In an alternative embodiment, the two or more different metal material layers 202 may further include a third metal material layer 2023 disposed between the first metal material layer 2021 and the inorganic insulating material layer 201. Here, the third metal material layer 2023 may include or consist of a dissimilar metal material having a corrosion potential difference compared to the metal material of the first metal material layer 2021. In an embodiment, the third metal material layer 2023 may include or consist of titanium (Ti) or molybdenum (Mo), for example.

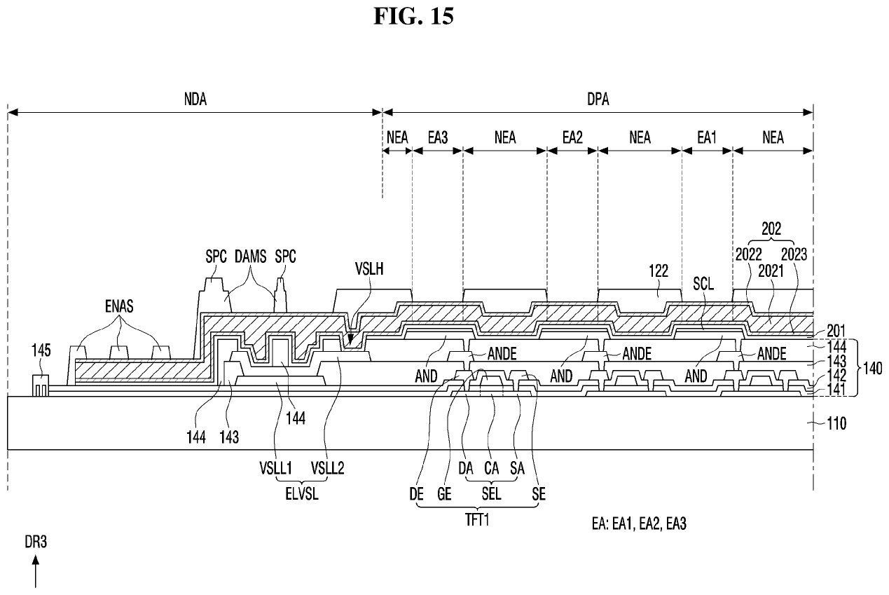

Referring to FIG. 15, the pixel defining layer 122, the dam structure DAMS, and the encapsulation auxiliary structure ENAS are disposed on the two or more different metal material layers 202 (operation S23).

Operation S23 of disposing the pixel defining layer 122, the dam structure DAMS, and the encapsulation auxiliary structure ENAS may include a process of removing a part of the organic insulating material layer (not shown) on the metal material layers 202.

The pixel defining layer 122 corresponds to the non-emission area NEA of the display area DPA.

The dam structure DAMS may correspond to the region of the non-display area NDA adjacent to the edge of the display area DPA and surround the edge of the display area DPA. At least two dam structures DAMS may be provided to be spaced apart from each other.

The encapsulation auxiliary structure ENAS may correspond to the region of the non-display area NDA between the dam structure DAMS and the edge of the substrate 110, and may surround a part of the edge of the display area DPA while being spaced apart from the pad area PDA. At least two encapsulation auxiliary structures ENAS may be provided to be spaced apart from each other. In an alternative embodiment, in order to improve reliability of encapsulation, at least three encapsulation auxiliary structures ENAS may be provided to be spaced apart from each other.

In operation S23 of disposing the pixel defining layer 122, the dam structure DAMS, and the encapsulation auxiliary structure ENAS, the spacer SPC disposed on a part of the pixel defining layer 122 and the dam structure DAMS may be provided together.

In this case, operation S23 of disposing the pixel defining layer 122, the dam structure DAMS, and the encapsulation auxiliary structure ENAS may include a process of providing an exposure mask by an exposure process using a halftone mask, a process of removing a part of the organic insulating material layer on the metal material layers 202 that does not correspond to the spacer SPC, the pixel defining layer 122, the dam structure DAMS, and the encapsulation auxiliary structure ENAS using the exposure mask, a process of changing the exposure mask, and a process of providing the pixel defining layer 122, the dam structure DAMS, and the encapsulation auxiliary structure ENAS by thinly patterning a part of the remaining organic insulating material layer except the spacer SPC using the changed exposure mask.

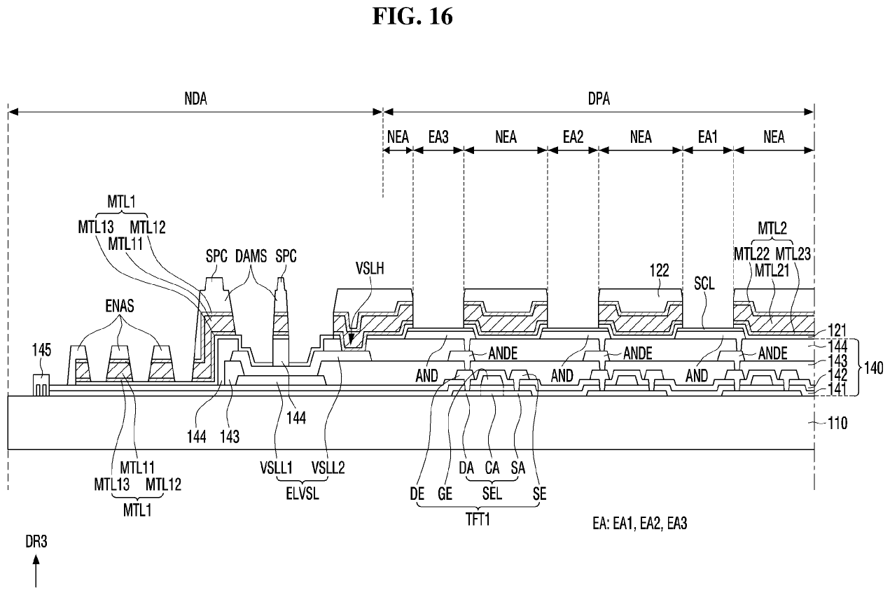

Referring to FIG. 16, the first multilayer MTL1 and the second multilayer MTL2 including or consisting of the metal material layers 202, and the bank buffer layer 121 including or consisting of the inorganic insulating material layer 201 may be provided (operation S24).

Operation S24 of providing the first multilayer MTL1, the second multilayer MTL2, and the bank buffer layer 121 may include a process of simultaneously patterning the metal material layers 202 and the inorganic insulating material layer 201 while using the pixel defining layer 122, the dam structure DAMS, and the encapsulation auxiliary structure ENAS as the mask.

Accordingly, the first multilayer MTL1 including or consisting of the metal material layers 202 remaining under each of the dam structure DAMS and the encapsulation auxiliary structure ENAS may be provided, the second multilayer MTL2 including or consisting of the metal material layers 202 remaining under the pixel defining layer 122 may be provided, and the bank buffer layer 121 including or consisting of the inorganic insulating material layer 201 remaining under each of the first multilayer MTL1 and the second multilayer MTL2 may be provided.

The first multilayer MTL1 may include the first main layer MTL11 including or consisting of the first metal material layer 2021, and the first cover layer MTL12 including or consisting of the second metal material layer 2022. In an alternative embodiment, the first multilayer MTL1 may further include the first support layer MTL13 including or consisting of the third metal material layer 2023.

Similarly, the second multilayer MTL2 may include the second main layer MTL21 including or consisting of the first metal material layer 2021, and the second cover layer MTL22 including or consisting of the second metal material layer 2022. In an alternative embodiment, the second multilayer MTL2 may further include the second support layer MTL23 including or consisting of the third metal material layer 2023.

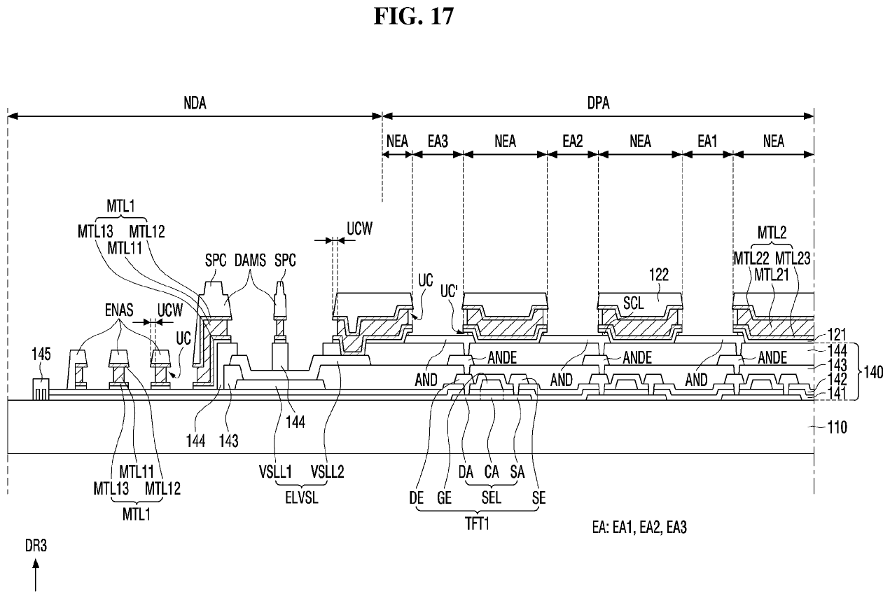

Referring to FIG. 17, by a process of patterning the first main layer MTL11, the second main layer MTL21, and the plurality of sacrificial layers SCL, each of the first multilayer MTL1 and the second multilayer MTL2 may be deformed into an undercut structure UC, and the plurality of anode electrodes AND may be exposed (operation S25).

That is, since the galvanic corrosion effect of the first main layer MTL11 is induced compared to the first cover layer MTL12, the first cover layer MTL12 may have the edge protruding beyond the first main layer MTL11. Accordingly, the first multilayer MTL1 may have the undercut structure UC.

Similarly, since the galvanic corrosion effect of the second main layer MTL21 is induced compared to the second cover layer MTL22, the second cover layer MTL22 may have the edge protruding beyond the second main layer MTL21. Accordingly, the second multilayer MTL2 may have the undercut structure UC.

In this case, a width UCW of the eaves according to the undercut structure UC may be selected within a range of about 0.3 μm to about 0.7 μm.

Further, at least a part of each of the plurality of sacrificial layers SCL is etched together with the first main layer MTL11 and the second main layer MTL21, so that the plurality of anode electrodes AND may be exposed.

In this case, a part of each of the plurality of sacrificial layers SCL may remain depending on the etching strength for the first main layer MTL11 and the second main layer MTL21. In this case, the bank buffer layer 121 covering the edge of each anode electrode AND has the edge protruding beyond the remaining sacrificial layer SCL. Accordingly, an undercut structure UC′ between the bank buffer layer 121 and the sacrificial layer SCL may be provided. Further, the bank buffer layer 121 covering the edge of each anode electrode AND is spaced apart from the edge of each anode electrode AND in the third direction DR3.

In an alternative embodiment, although not shown separately, all of the plurality of sacrificial layers SCL may be removed depending on the etching strength for the first main layer MTL11 and the second main layer MTL21. Even in this case, the bank buffer layer 121 covering the edge of each anode electrode AND is spaced apart from the edge of each anode electrode AND in the third direction DR3, and thus may be provided in the form of eaves with respect to the edge of each anode electrode AND.

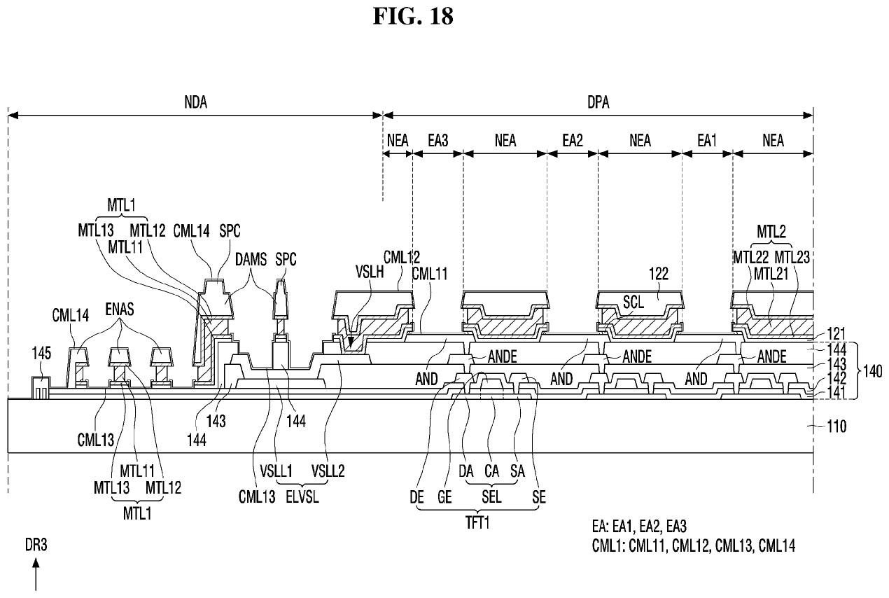

Referring to FIG. 18, the first common layer CML1 corresponding to the entirety of the area of the substrate 110 is disposed on the plurality of anode electrodes AND, the pixel defining layer 122, the dam structure DAMS, and the encapsulation auxiliary structure ENAS (operation S31).

In an embodiment, operation S31 of disposing the first common layer CML1 may include a process of stacking an organic material having a hole transporting property without a mask. In an alternative embodiment, operation S31 of disposing the first common layer CML1 may include a process of stacking an organic material having a hole injecting property without a mask and a process of stacking an organic material having a hole transporting property without a mask, for example.

The first common layer CML1 may be separated by the undercut structure of the first multilayer MTL1 and the undercut structure of the second multilayer MTL2.

That is, in the display area DPA, the first common layer CML11 corresponding to each emission area EA and disposed on the anode electrode AND may be separated from the first common layer CML12 disposed on the pixel defining layer 122 by the undercut structure of the second multilayer MTL2.

Further, in the non-display area NDA, the first common layer CML13 corresponding to the periphery of each of the dam structure DAMS and the encapsulation auxiliary structure ENAS may be separated from the first common layer CML14 disposed on each of the dam structure DAMS and the encapsulation auxiliary structure ENAS by the undercut structure of the first multilayer MTL1.

Next, the plurality of light-emitting layers EML respectively corresponding to the plurality of emission areas EA are disposed (operation S32).

The plurality of emission areas EA may include the first emission area EA1 emitting light of the first color, the second emission area EA2 emitting light of the second color having a wavelength band lower than that of the first color, and the third emission area EA3 emitting light of the third color having a wavelength band lower than that of the second color.

Operation S32 of disposing the plurality of light-emitting layers EML may include a process of disposing the first light-emitting layer EML1 generating light of the first color on the anode electrode AND of the first emission areas EA1, a process of disposing the second light-emitting layer EML2 generating light of the second color on the anode electrode AND of the second emission areas EA2, and a process of disposing the third light-emitting layer EML3 generating light of the third color on the anode electrode AND of the third emission areas EA3. In this case, the arrangement order of the first light-emitting layer EML1, the second light-emitting layer EML2, and the third light-emitting layer EML3 may be changed depending on process convenience.

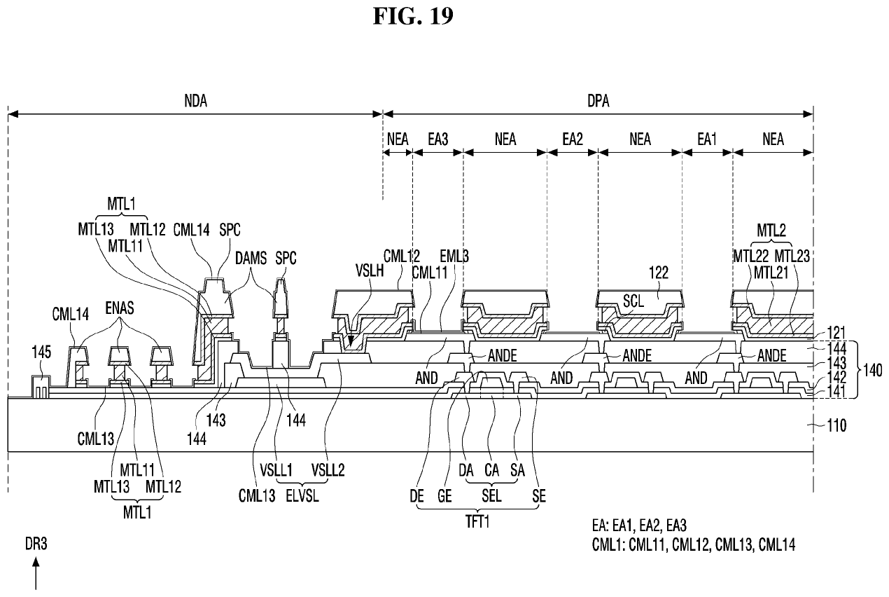

Referring to FIG. 19, the third light-emitting layer EML3 may be disposed on the anode electrode AND of the third emission areas EA3 using a mask (not shown) defining openings corresponding to the third emission areas EA3.

The third light-emitting layer EML3 may include or consist of a dopant material or a host material that generates light of the third color by the driving current applied between the anode electrode AND and the cathode electrode CTD.

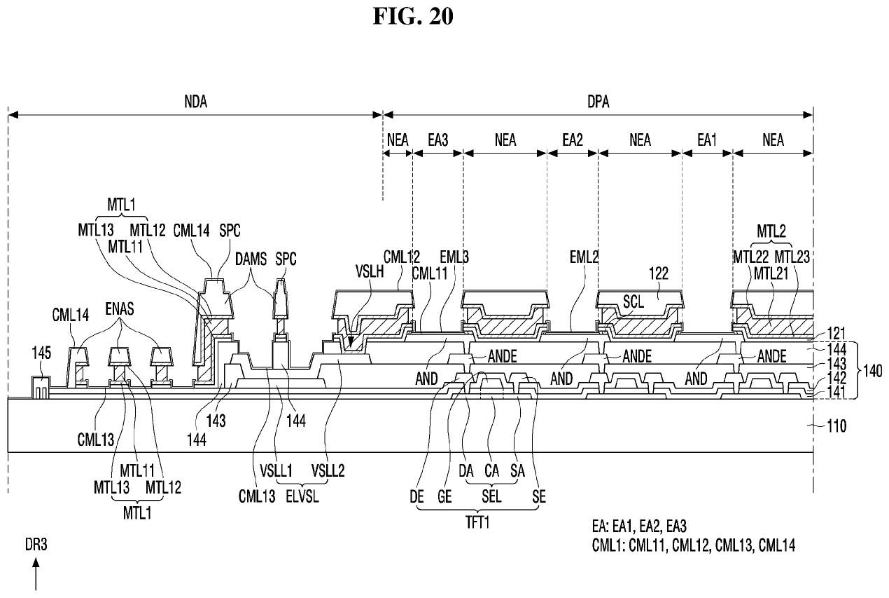

Referring to FIG. 20, the second light-emitting layer EML2 may be disposed on the anode electrode AND of the second emission areas EA2 using a mask (not shown) defining openings corresponding to the second emission areas EA2.

The second light-emitting layer EML2 may include or consist of a dopant material or a host material that generates light of the second color having a wavelength band higher than that of the third color by the driving current applied between the anode electrode AND and the cathode electrode CTD.

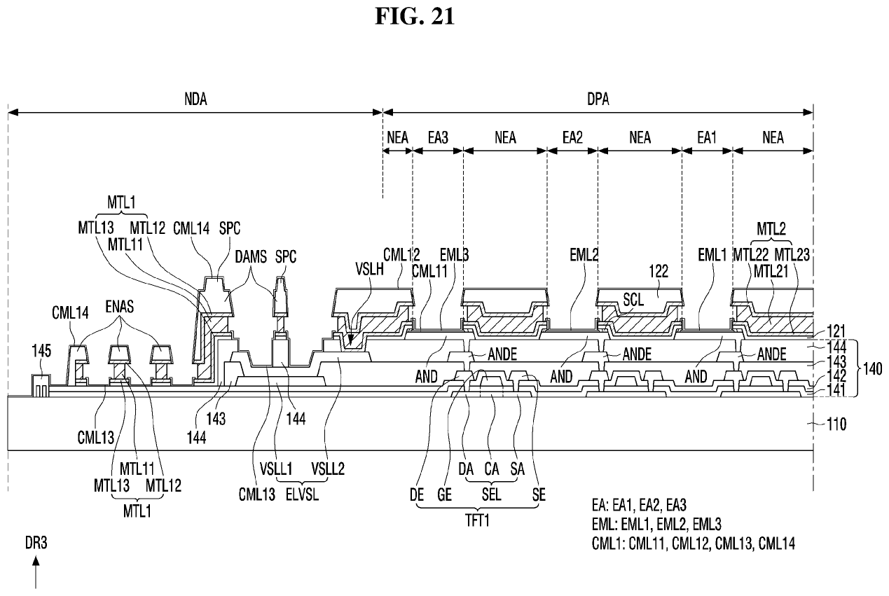

Referring to FIG. 21, the first light-emitting layer EML1 may be disposed on the anode electrode AND of the first emission areas EA1 using a mask (not shown) defining openings corresponding to the first emission areas EA1.

The first light-emitting layer EML1 may include or consist of a dopant material or a host material that generates light of the first color having a wavelength band higher than that of the second color by the driving current applied between the anode electrode AND and the cathode electrode CTD.

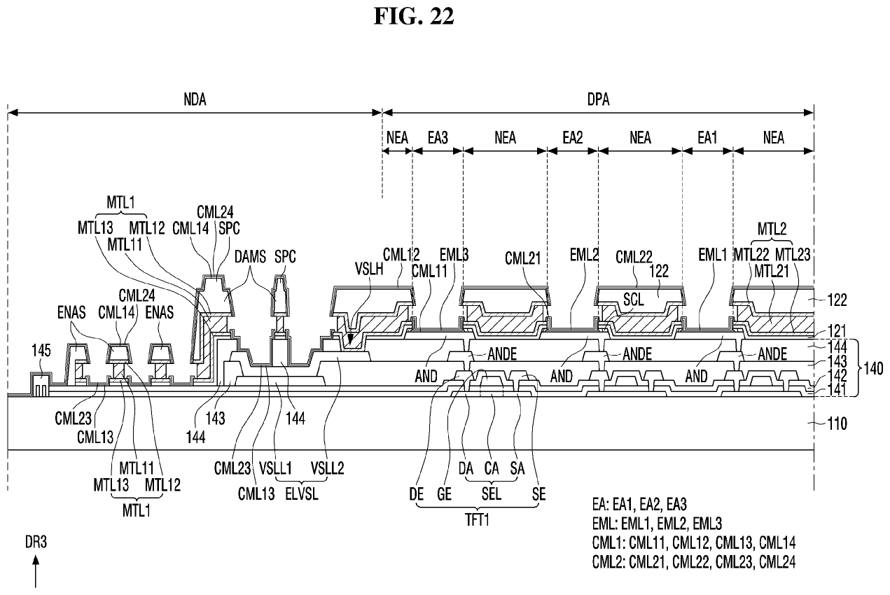

Referring to FIG. 22, the second common layer CML2 corresponding to the entirety of the area of the substrate 110 is disposed on the plurality of light-emitting layers EML and the first common layer CML1 (operation S33).

In an embodiment, operation S33 of disposing the second common layer CML2 may include a process of stacking an organic material having an electron transporting property without a mask, for example. In an alternative embodiment, operation S33 of disposing the second common layer CML2 may include a process of stacking an organic material having an electron injecting property without a mask and a process of stacking an organic material having an electron transporting property.

The second common layer CML2 may be separated by the undercut structure of the first multilayer MTL1 and the undercut structure of the second multilayer MTL2.

That is, in the display area DPA, the second common layer CML21 corresponding to each emission area EA and disposed on the anode electrode AND may be separated from the second common layer CML22 on the pixel defining layer 122 by the undercut structure of the second multilayer MTL2.

Further, in the non-display area NDA, the second common layer CML23 corresponding to the periphery of each of the dam structure DAMS and the encapsulation auxiliary structure ENAS may be separated from the second common layer CML24 disposed on each of the dam structure DAMS and the encapsulation auxiliary structure ENAS by the undercut structure of the first multilayer MTL1.

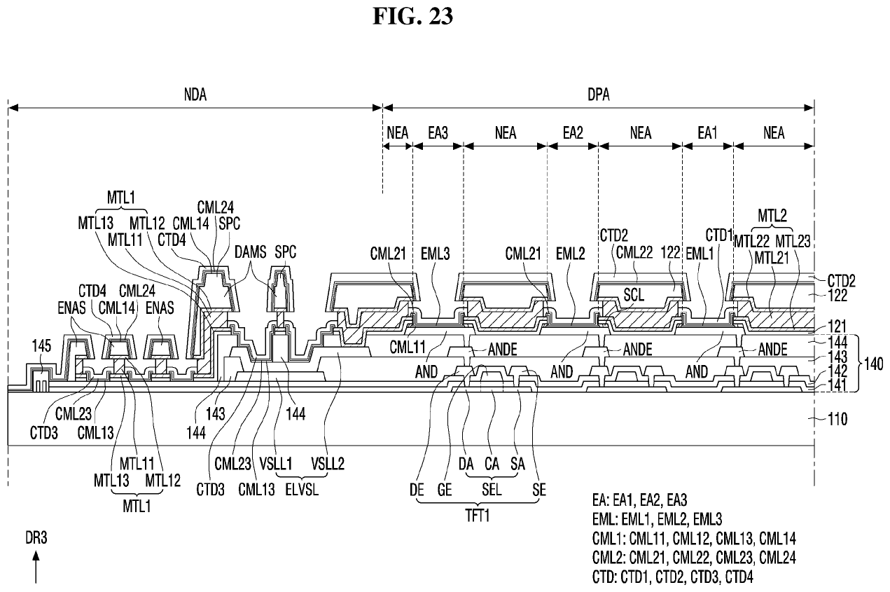

Referring to FIG. 23, the cathode electrode CTD corresponding to the entirety of the area of the substrate 110 is disposed on the second common layer CML2 (operation S34).

In an embodiment, operation S34 of disposing the cathode electrode CTD may include a process of stacking a conductive material without a mask, for example.

In this case, the cathode electrode CTD may include a transparent metal oxide material such as ITO, IZO, and IGZO.

The cathode electrode CTD may be separated by the undercut structure of the first multilayer MTL1 and the undercut structure of the second multilayer MTL2.

That is, in the display area DPA, the cathode electrode CTD1 corresponding to each emission area EA and disposed on the anode electrode AND may be separated from on the cathode electrode CTD2 disposed on the pixel defining layer 122 by the undercut structure of the second multilayer MTL2.

Further, in the display area DPA, the cathode electrode CTD1 corresponding to each emission area EA contacts and electrically connected to the second multilayer MTL2 adjacent thereto.

The second multilayer MTL2 may be electrically connected to the second wiring pattern layer VSLL2 of a second power line ELVSL through a second power line contact hole VSLH of the non-display area NDA.

Accordingly, the second multilayer MTL2 may function as an auxiliary line connecting the cathode electrode CTD1 of the plurality of emission areas EA and the second power line ELVSL.

In the non-display area NDA, the cathode electrode CTD3 corresponding to the periphery of each of the dam structure DAMS and the encapsulation auxiliary structure ENAS may be separated from the cathode electrode CTD4 disposed on each of the dam structure DAMS and the encapsulation auxiliary structure ENAS by the undercut structure of the first multilayer MTL1.

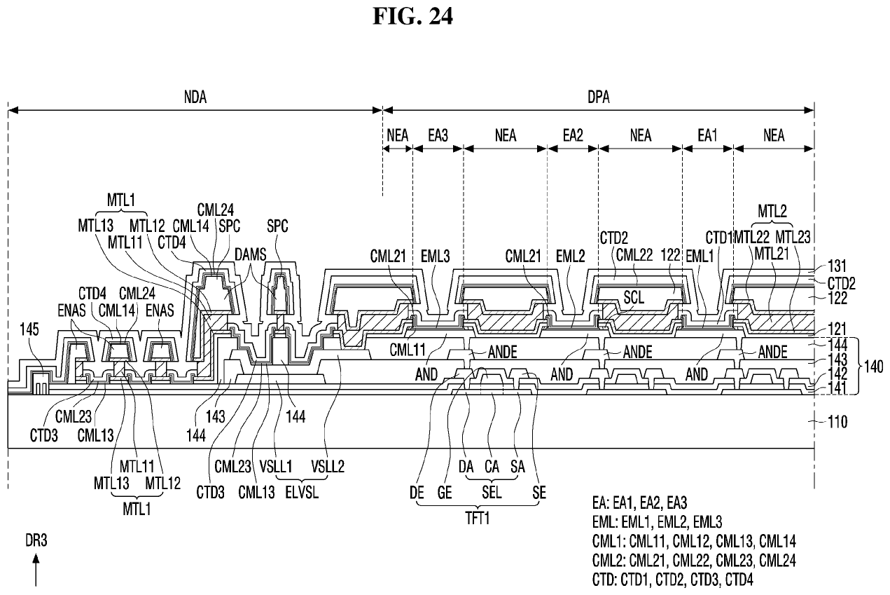

Referring to FIG. 24, the first encapsulation layer 131 corresponding to the entirety of the area of the substrate 110 is disposed on the cathode electrode CTD (operation S41).

In an embodiment, operation S41 of disposing the first encapsulation layer 131 may include a process of stacking an inorganic insulating material by a CVD method without a mask, for example.

The first encapsulation layer 131 disposed by the CVD method may be stacked along the undercut structure of the first multilayer MTL1 in the non-display area NDA, and thus may be bonded to the first main layer MTL11 protected by the eaves of the first cover layer MTL12.

Therefore, even when the first common layer CML1, the second common layer CML2, and the cathode electrode CTD correspond to the entirety of the area of the substrate 110, the encapsulation structure formed by bonding between inorganic materials by the first encapsulation layer 131 and the first multilayer MTL1 may be provided.

Further, the first encapsulation layer 131 may be stacked along the undercut structure of the second multilayer MTL2 in the display area DPA, and thus may contact the second main layer MTL21 protected by the eaves of the second cover layer MTL22.

Therefore, due to bonding between the inorganic materials by the first encapsulation layer 131 and the second multilayer MTL2, the plurality of light-emitting layers EML corresponding to the plurality of emission areas EA may be individually encapsulated.

Accordingly, even when a mask is not used at the time of disposing the first common layer CML1, the second common layer CML2, and the cathode electrode CTD, the encapsulation structure formed by bonding between inorganic materials may be provided. Accordingly, it is possible to prevent acceleration of deterioration due to permeation of oxygen or moisture or reduction in the lifetime of the display device 100, and also possible to simplify and facilitate the fabricating process.

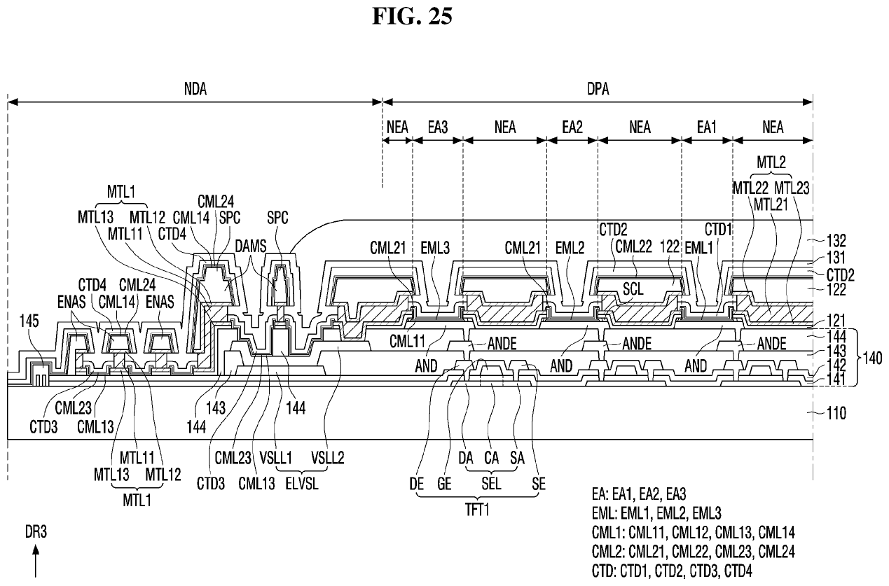

Referring to FIG. 25, the second encapsulation layer 132 corresponding to the region surrounded by the dam structure DAMS is disposed on the first encapsulation layer 131 (operation S42).

Operation S42 of disposing the second encapsulation layer 132 may include a process of dropping an organic insulating material on the first encapsulation layer 131, a process of spreading the dropped organic insulating material to correspond to the region surrounded by the dam structure DAMS, and a process of curing the organic insulating material spread to correspond to the region surrounded by the dam structure DAMS.

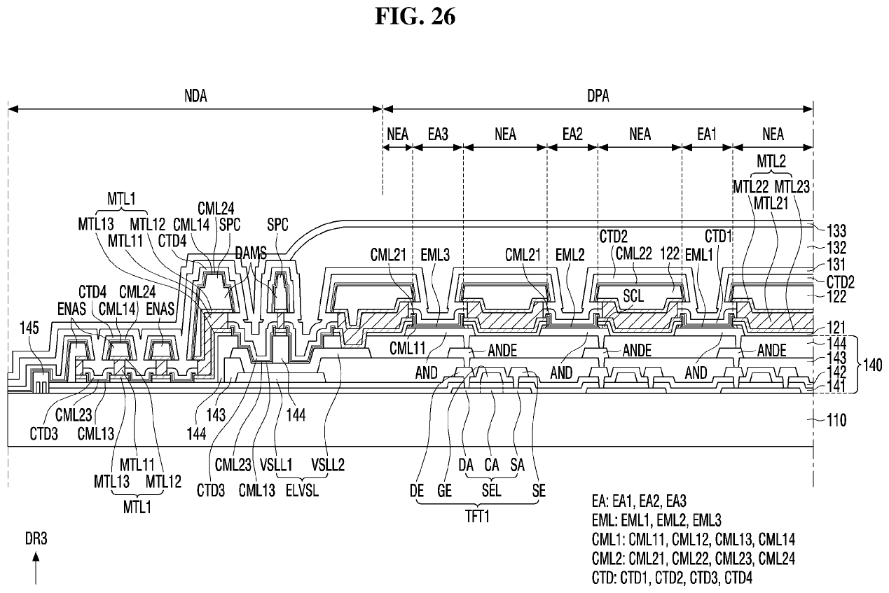

Referring to FIG. 26, the third encapsulation layer 133 corresponding to the entirety of the area of the substrate 110 and covering the second encapsulation layer 132 is disposed on the first encapsulation layer 131 (operation S43).

In an embodiment, operation S43 of disposing the third encapsulation layer 133 may include a process of stacking an inorganic insulating material by a CVD method without a mask, for example.

The third encapsulation layer 133 is bonded to the first encapsulation layer 131 near the dam structure DAMS in the non-display area NDA.

As described above, each of operation S31 of disposing the first common layer CML1, operation 33 of disposing the second common layer CML2, operation S34 of disposing the cathode electrode CTD, operation S41 of disposing the first encapsulation layer 131, and operation S43 of disposing the third encapsulation layer 133 is performed by a deposition process using no mask, so that the first common layer CML1, the second common layer CML2, the cathode electrode CTD, the first encapsulation layer 131, and the third encapsulation layer 133 corresponding to the entirety of the area of the substrate 110 are disposed.

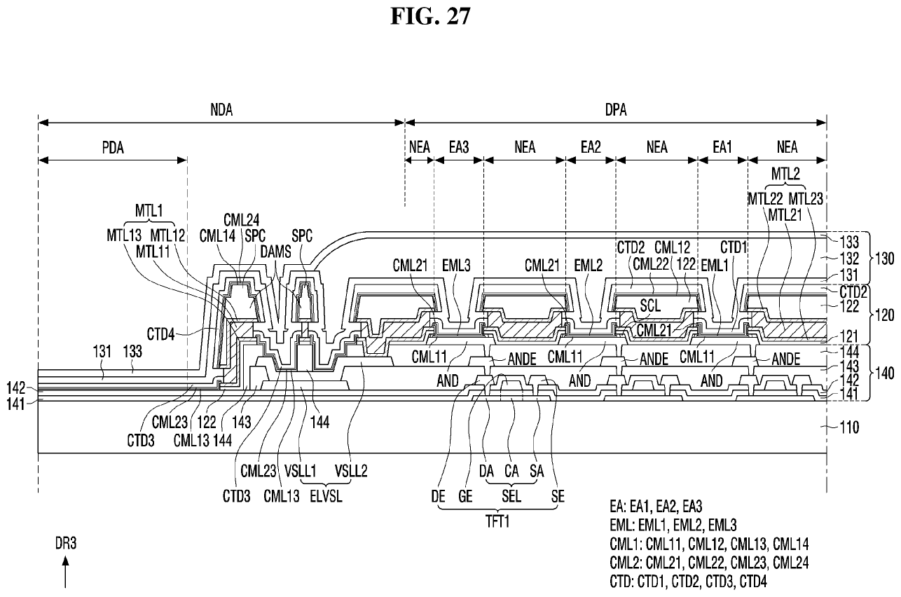

That is, referring to FIG. 27, after operation S43 of disposing the third encapsulation layer 133, the first common layer CML1, the second common layer CML2, the cathode electrode CTD, the first encapsulation layer 131, and the third encapsulation layer 133 are disposed in the entirety of the area of the substrate 110, so that the pads SPD of the pad area PDA are covered with the first common layer CML1, the second common layer CML2, the cathode electrode CTD, the first encapsulation layer 131, and the third encapsulation layer 133.

However, the pads SPD need to be exposed for connection of a circuit board (not shown).

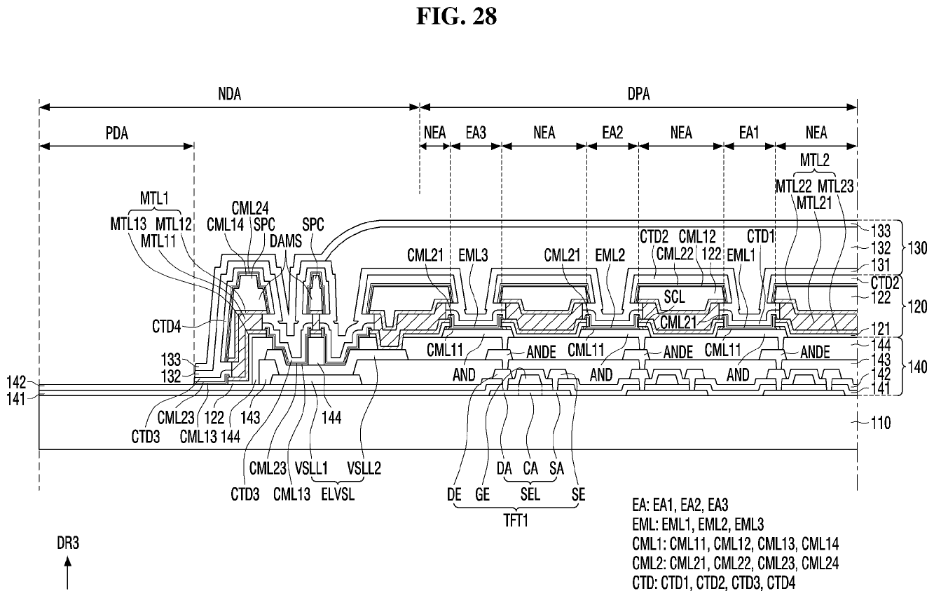

Accordingly, referring to FIG. 28, a part of each of the first common layer CML1, the second common layer CML2, the cathode electrode CTD, the first encapsulation layer 131, and the third encapsulation layer 133 corresponding to the pad area PDA is removed to expose the pads SPD of the pad area PDA (operation S50).

Operation S50 of exposing the pads SPD may include a process of performing patterning on the first common layer CML1, the second common layer CML2, the cathode electrode CTD, the first encapsulation layer 131, and the third encapsulation layer 133 using a mask (not shown) defining an opening corresponding to the pad area PDA. In an embodiment, operation S50 of exposing the pads SPD may include a process of performing dry etching on the cathode electrode CTD, the first encapsulation layer 131, and the third encapsulation layer 133 in a state where a mask (not shown) defining the opening corresponding to the pad area PDA is disposed, and a process of performing a plasma etching process or an ashing process on the first common layer CML1 and the second common layer CML2, for example.

Accordingly, a part of each of the first common layer CML1, the second common layer CML2, the cathode electrode CTD, the first encapsulation layer 131, and the third encapsulation layer 133 corresponding to the pad area PDA may be removed.

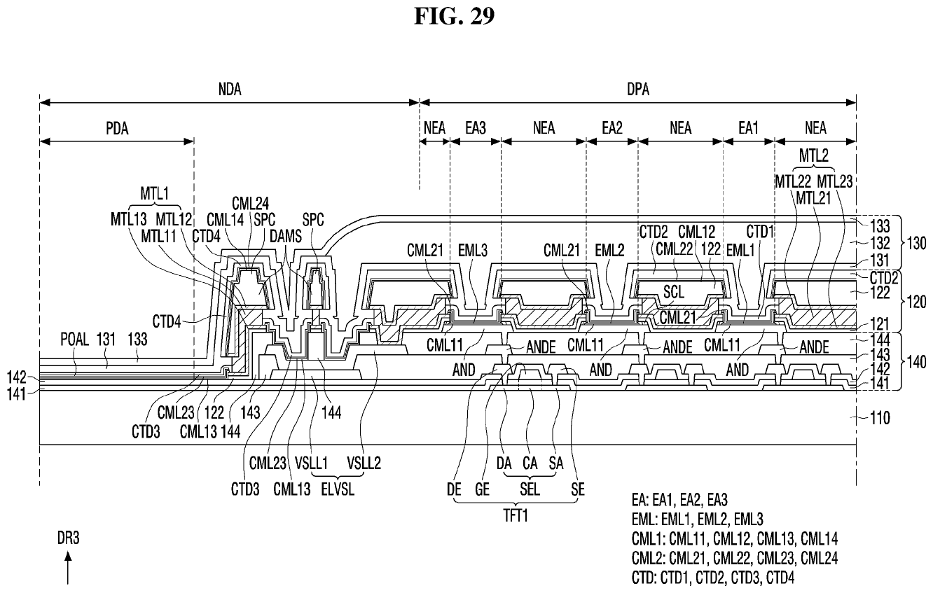

In an alternative embodiment, referring to FIG. 29, before operation S31 of disposing the first common layer CML1, a peel-off auxiliary layer POAL corresponding to the pad area PDA may be disposed.

That is, in the pad area PDA, the first common layer CML1 may be disposed on the peel-off auxiliary layer POAL.

In an embodiment, the peel-off auxiliary layer POAL may be provided in the form of a film and may be attached on the inter-insulating layer 142 of the pad area PDA to cover the pads SPD of the pad area PDA, for example.

In an alternative embodiment, the peel-off auxiliary layer POAL may be disposed on the pads SPD of the pad area PDA by an inkjet printing method.

In this case, operation S50 of exposing the pads SPD of the pad area PDA may include a process of weakening the adhesive force of the peel-off auxiliary layer POAL, and a process of separating the peel-off auxiliary layer POAL from the pads SPD.

Referring to FIGS. 30, 31 and 32, a method of fabricating the display device 100′ in another embodiment is substantially the same as the method of fabricating the display device 100 in an embodiment of FIGS. 10 to 29 except that it further includes a process of disposing the planarization auxiliary layer 151 corresponding to the area of the substrate 110 except the pad area PDA on the third encapsulation layer 133 and a process of disposing the touch unit support layer 152 covering the planarization auxiliary layer 151, so that redundant description will be omitted in the following description.

The process of disposing the planarization auxiliary layer 151 on the third encapsulation layer 133 and the process of disposing the touch unit support layer 152 may be performed before operation S50 of exposing the pads SPD of the pad area PDA.

In this case, the process of disposing the planarization auxiliary layer 151 on the third encapsulation layer 133 and the process of disposing the touch unit support layer 152 may be performed on the entirety of the area of the substrate 110. In addition, operation S50 of exposing the pads SPD may further include a process of removing a part of the touch unit support layer 152 corresponding to the pad area PDA, and a process of removing a part of the planarization auxiliary layer 151 corresponding to the pad area PDA.

In an alternative embodiment, the process of disposing the planarization auxiliary layer 151 on the third encapsulation layer 133 and the process of disposing the touch unit support layer 152 may be performed after operation S50 of exposing the pads SPD of the pad area PDA.

In this case, each of the process of disposing the planarization auxiliary layer 151 on the third encapsulation layer 133 and the process of disposing the touch unit support layer 152 may be performed on the area of the substrate 110 except the pad area PDA.

Further, the touch unit support layer 152 covering the planarization auxiliary layer 151 may contact the inter-insulating layer 142 at the edge of the pad area PDA.

As described above, in the embodiments, a mask for providing an encapsulation structure formed by bonding between inorganic materials may be omitted, so that the process may be facilitated and simplified.

However, the effects of the disclosure are not restricted to the one set forth herein. The above and other effects of the disclosure will become more apparent to one of daily skill in the art to which the disclosure pertains by referencing the claims.

What is claimed is:

1. A display device comprising:
a substrate comprising:
a display area in which a plurality of emission areas displays an image; and
a non-display area disposed around the display area;
a light-emitting array layer disposed in the display area on the substrate;
an encapsulation structure disposed on the substrate and covering the light-emitting array layer;
pads disposed in a pad area which is a part of the non-display area on the substrate;
a dam structure disposed in the non-display area on the substrate and surrounding an edge of the display area;
an encapsulation auxiliary structure corresponding to another part of the non-display area except the pad area, surrounding a part of the edge of the display area, and disposed between the dam structure and an edge of the substrate; and
a first multilayer disposed between the substrate and each of the dam structure and the encapsulation auxiliary structure, and comprising an undercut structure by two or more different metal materials which are stacked.

2. The display device of claim 1, wherein the first multilayer comprises a first main layer, and a first cover layer disposed on the first main layer, wherein the first main layer and the first cover layer comprise different metal materials from each other, and
the undercut structure of the first multilayer is provided by the first cover layer including an edge protruding beyond the first main layer.

3. The display device of claim 2, wherein the encapsulation structure comprises:
a first encapsulation layer corresponding to an area of the substrate except the pad area, covering the light-emitting array layer, and comprising an inorganic insulating material;
a second encapsulation layer disposed on the first encapsulation layer, comprising an organic insulating material, and corresponding to a region surrounded by the dam structure; and
a third encapsulation layer disposed on the first encapsulation layer, covering the second encapsulation layer, and comprising the inorganic insulating material,
wherein the first encapsulation layer contacts the first main layer of the first multilayer, and
the first encapsulation layer and the third encapsulation layer contact each other in an area between the dam structure and the edge of the substrate in the non-display area.

4. The display device of claim 3, wherein the light-emitting array layer comprises:
a plurality of anode electrodes respectively corresponding to the plurality of emission areas;
a bank buffer layer corresponding to a non-emission area which is a separation region between the plurality of emission areas and covering an edge of each of the plurality of anode electrodes;
a second multilayer disposed on the bank buffer layer, and comprising an undercut structure by two or more different metal materials which are stacked;
a pixel defining layer disposed on the second multilayer;
a first common layer disposed on the plurality of anode electrodes and the pixel defining layer;
a plurality of light-emitting layers respectively corresponding to the plurality of emission areas and disposed on the first common layer;
a second common layer disposed on the first common layer and covering the plurality of light-emitting layers; and
a cathode electrode disposed on the second common layer and corresponding to the plurality of emission areas,
wherein the first common layer, the second common layer, and the cathode electrode correspond to an area of the substrate except the pad area.

5. The display device of claim 4, wherein the second multilayer comprises a second main layer, and a second cover layer disposed on the second main layer, wherein the second main layer and the second cover layer comprise different metal materials from each other, and
the undercut structure of the second multilayer is provided by the second cover layer including an edge protruding beyond the second main layer, and
the first encapsulation layer covers the cathode electrode and contacts the second main layer of the second multilayer.

6. The display device of claim 5, wherein each of the first common layer, the second common layer, and the cathode electrode is separated by the undercut structure of the second multilayer disposed under the pixel defining layer, and
the cathode electrode comprises a plurality of portions respectively disposed on the plurality of anode electrodes,
the plurality of portions of the cathode electrode contacts the second main layer of the second multilayer and is electrically connected to each other through the second multilayer.

7. The display device of claim 5, wherein the bank buffer layer, the first common layer, the second common layer, and the cathode electrode extend to the another part of the non-display area except the pad area.

8. The display device of claim 7, wherein the first common layer, the second common layer, and the cathode electrode cover the dam structure and the encapsulation auxiliary structure, and
each of the first common layer, the second common layer, and the cathode electrode is separated by the undercut structure of the first multilayer disposed under each of the dam structure and the encapsulation auxiliary structure.

9. The display device of claim 5, wherein each of the first main layer and the second main layer comprises aluminum (Al) or copper (Cu), and
each of the first cover layer and the second cover layer comprises titanium (Ti) or molybdenum (Mo).

10. The display device of claim 5, wherein the first multilayer further comprises a first support layer disposed between the substrate and the first main layer and comprising a metal material different from the metal material of the first main layer, and
the second multilayer further comprises a second support layer disposed between the bank buffer layer and the second main layer and comprising a metal material different from the metal material of the second main layer.

11. The display device of claim 4, wherein the bank buffer layer is spaced apart from an upper portion of the edge of each of the plurality of anode electrodes.

12. The display device of claim 11, further comprising a sacrificial layer disposed between the bank buffer layer and each of the plurality of anode electrodes,
wherein the bank buffer layer includes an edge protruding beyond the sacrificial layer.

13. The display device of claim 4, wherein the first multilayer and the second multilayer are provided in a same layer, and
the dam structure, the encapsulation auxiliary structure, and the pixel defining layer are provided in a same layer.

14. The display device of claim 4, further comprising a circuit array layer disposed on the substrate and comprising a plurality of pixel drivers respectively corresponding to the plurality of emission areas,
wherein each of the plurality of pixel drivers comprises at least one transistor,
each of the at least one transistor comprises a semiconductor layer disposed on the substrate, a gate electrode disposed on a gate insulating layer covering the semiconductor layer, and a source electrode and a drain electrode disposed on an inter-insulating layer covering the gate electrode,
the circuit array layer comprises:
a first planarization layer disposed on the inter-insulating layer and covering the at least one transistor of each of the plurality of pixel drivers;
a plurality of anode connection electrodes disposed on the first planarization layer and connected to the plurality of pixel drivers, respectively; and
a second planarization layer covering the plurality of anode connection electrodes,
the plurality of anode electrodes is disposed on the second planarization layer and is respectively connected to the plurality of anode connection electrodes,
the dam structure is disposed on the second planarization layer, and
the encapsulation auxiliary structure is disposed on the inter-insulating layer.

15. A method of fabricating a display device, the method comprising:
providing a substrate comprising a display area in which a plurality of emission areas displays an image, and a non-display area disposed around the display area;
disposing a circuit array layer on the substrate, the circuit array layer comprising a plurality of pixel drivers respectively corresponding to the plurality of emission areas, and pads in a pad area which is a part of the non-display area;
disposing a plurality of anode electrodes respectively corresponding to the plurality of emission areas and a plurality of sacrificial layers respectively stacked on the plurality of anode electrodes on the circuit array layer;
disposing an inorganic insulating material layer covering the plurality of sacrificial layers on the circuit array layer;
disposing two or more metal material layers different from each other on the inorganic insulating material layer;
disposing a pixel defining layer corresponding to a non-emission area which is a separation region between the plurality of emission areas, a dam structure corresponding to the non-display area and surrounding an edge of the display area, and an encapsulation auxiliary structure corresponding to another part of the non-display area except the pad area, surrounding a part of the edge of the display area, and disposed between the dam structure and an edge of the substrate on the two or more metal material layers;
patterning the two or more metal material layers and the inorganic insulating material layer using the pixel defining layer, the dam structure, and the encapsulation auxiliary structure as a mask, providing a first multilayer comprising the two or more metal material layers remaining under each of the dam structure and the encapsulation auxiliary structure, providing a second multilayer comprising the two or more metal material layers remaining under the pixel defining layer, and providing a bank buffer layer comprising the inorganic insulating material layer remaining under each of the first multilayer and the second multilayer;
deforming the first multilayer and the second multilayer into an undercut structure, patterning the plurality of sacrificial layers and exposing the plurality of anode electrodes;
disposing a first common layer corresponding to an entirety of the area of the substrate on the plurality of anode electrodes, the pixel defining layer, the dam structure, and the encapsulation auxiliary structure;
disposing a plurality of light-emitting layers respectively corresponding to the plurality of emission areas on the first common layer;
disposing a second common layer corresponding to the entirety of the area of the substrate and covering the plurality of light-emitting layers on the first common layer;
disposing a cathode electrode corresponding to the entirety of the area of the substrate on the second common layer;
disposing a first encapsulation layer corresponding to the entirety of the area of the substrate on the cathode electrode;
disposing a second encapsulation layer corresponding to a region surrounded by the dam structure on the first encapsulation layer;
disposing a third encapsulation layer corresponding to the entirety of the area of the substrate and covering the second encapsulation layer on the first encapsulation layer; and
removing a part of each of the first common layer, the second common layer, the cathode electrode, the first encapsulation layer, and the third encapsulation layer corresponding to the pad area, and exposing the pads.

16. The method of claim 15, wherein in the removing the part of each of the first common layer, the second common layer, the cathode electrode, the first encapsulation layer, and the third encapsulation layer corresponding to the pad area, an etching process is performed on the first common layer, the second common layer, the cathode electrode, the first encapsulation layer, and the third encapsulation layer using a mask in which an opening corresponding to the pad area is defined.

17. The method of claim 15, further comprising, before disposing the first common layer, disposing a peel-off auxiliary layer corresponding to the pad area on the circuit array layer,
wherein in the removing the part of each of the first common layer, the second common layer, the cathode electrode, the first encapsulation layer, and the third encapsulation layer corresponding to the pad area, an etching process is performed on the first common layer, the second common layer, the cathode electrode, the first encapsulation layer, and the third encapsulation layer using the peel-off auxiliary layer.

18. The method of claim 15, wherein in the sequentially stacking the two or more metal material layers, the two or more metal material layers comprise a first metal material layer disposed on the inorganic insulating material layer, and a second metal material layer disposed on the first metal material layer, wherein the first main layer and a first cover layer comprise different metal materials from each other, and
wherein in the providing the first multilayer and the second multilayer, the first multilayer comprises a first main layer including the first metal material layer, and a first cover layer disposed on the first main layer and including the second metal material layer, and the second multilayer comprises a second main layer including the first metal material layer, and a second cover layer disposed on the second main layer and including the second metal material layer.

19. The method of claim 18, wherein in the deforming the first multilayer and the second multilayer into the undercut structure, the patterning the plurality of sacrificial layers and the exposing the plurality of anode electrodes,
patterning is performed on the plurality of sacrificial layers, the first main layer, and the second main layer,
an edge of the first cover layer protrudes beyond the first main layer and deforms the first multilayer into the undercut structure,
an edge of the second cover layer protrudes beyond the second main layer and deforms the second multilayer into the undercut structure, and
at least a part of each of the plurality of sacrificial layers is removed and exposes the plurality of anode electrodes.

20. The method of claim 19, wherein in the deforming the first multilayer and the second multilayer into the undercut structure, and the patterning the plurality of sacrificial layers and the exposing the plurality of anode electrodes,
the bank buffer layer is spaced apart from an upper portion of an edge of each of the plurality of anode electrodes.

21. The method of claim 19, wherein in the deforming the first multilayer and the second multilayer into the undercut structure, the patterning the plurality of sacrificial layers and the exposing the plurality of anode electrodes, the bank buffer layer includes an edge protruding beyond a remaining portion of each of the plurality of sacrificial layers.

22. The method of claim 19, wherein in the disposing the first common layer, the first common layer disposed on the plurality of anode electrodes is separated from the first common layer disposed on the pixel defining layer by the undercut structure of the second multilayer, and the first common layer disposed on the circuit array layer of the non-display area is separated from the first common layer disposed on each of the dam structure and the encapsulation auxiliary structure,
wherein in the disposing the second common layer, the second common layer disposed on the plurality of anode electrodes is separated from the second common layer disposed on the pixel defining layer by the undercut structure of the second multilayer, and the second common layer disposed on the circuit array layer of the non-display area is separated from the second common layer disposed on each of the dam structure and the encapsulation auxiliary structure, and
wherein in the disposing the cathode electrode, the cathode electrode disposed on the plurality of anode electrodes is separated from the cathode electrode disposed on the pixel defining layer by the undercut structure of the second multilayer, and the cathode electrode disposed on the circuit array layer of the non-display area is separated from the cathode electrode disposed on each of the dam structure and the encapsulation auxiliary structure.

23. The method of claim 22, wherein in the disposing the first encapsulation layer, the first encapsulation layer contacts each of the first main layer and the second main layer.

24. The method of claim 22, wherein in the disposing the cathode electrode, the cathode electrode comprises portions respectively disposed above the plurality of anode electrodes,
the portions of the cathode electrode contact the second main layer of the second multilayer and are electrically connected to each other through the second multilayer.

25. The method of claim 15, wherein in the disposing the third encapsulation layer, the third encapsulation layer contacts the first encapsulation layer in a partial area between the edge of the substrate and the dam structure in the non-display area.
